(19) United States
(12) Patent Application Publication
(10) Pub. No.: US 2025/0081441 A1
(43) Pub. Date: Mar. 6, 2025

(54) SEMICONDUCTOR MEMORY DEVICE AND METHOD FOR MANUFACTURING THE SAME

(71) Applicant: Samsung Electronics Co., Ltd., Suwon-si (KR)

(72) Inventors: Bowon YOO, Suwon-si (KR); Seokhan PARK, Suwon-si (KR); Gyuhwan OH, Suwon-si (KR); Jinwoo HAN, Suwon-si (KR)

(73) Assignee: Samsung Electronics Co., Ltd., Suwon-si (KR)

(21) Appl. No.: 18/414,959

(22) Filed: Jan. 17, 2024

(30) Foreign Application Priority Data
Aug. 30, 2023 (KR) 10-2023-0114647

(51) Int. Cl. H10B 12/00

(52) U.S. Cl. CPC H10B 12/482; H10B 12/315; H10B 12/488; H10B 12/50

(57) ABSTRACT

A semiconductor memory device includes a bit line on a peripheral gate structure and extending in a second direction different from a first direction; a shielding structure adjacent to the bit line on the peripheral gate structure and extending in the second direction; a back gate electrode on the bit line and the shielding structure and extending in the first direction; a first word line extending in the first direction and on one side of the back gate electrode in the second direction, and a second word line placed on another side of the back gate electrode, the first and second word lines on the bit line and the shielding structure; and a first activation pattern between the back gate electrode and the first word line and a second activation pattern, the first and second activation patterns on the bit line, wherein the shielding structure includes a low-dielectric material.

### CROSS-REFERENCE TO RELATED APPLICATION

This application claims priority to and the benefit of Korean Patent Application No. 10-2023-0114647 filed in the Korean Intellectual Property Office on Aug. 30, 2023, the entire contents of which are incorporated herein by reference.

### BACKGROUND

Various example embodiments relate to a semiconductor memory device and/or a method for manufacturing the same, and in detail, to a semiconductor memory device including a vertical channel transistor (VCT) and/or a method for manufacturing the same.

There is a need or a desire to increase an integration of semiconductor memory devices so as to meet or help to meet improved excellent performances and/or low prices expected by consumers. In the case of the semiconductor memory devices, particularly improved integration is required or desired because the integration is an important factor in determining the price of the product.

In the case of two-dimensional or planar semiconductor memory devices, the integration is mainly determined by the area occupied by a unit memory cell, so it is greatly affected by a level of a fine pattern formation technology. However, because ultra-expensive equipment is required or used for a pattern miniaturization, although the integration of two-dimensional semiconductor memory devices is increasing, it is still limited. Accordingly, the semiconductor memory devices including a vertical channel transistor of which a channel extends in a vertical direction are being proposed.

### SUMMARY

Various example embodiments may provide a semiconductor memory device and/or a method for manufacturing the same, which may sufficiently prevent or help to prevent or reduce a coupling between bit lines without a conductive shielding structure by sufficiently isolating the bit lines, while improving an integration by reducing a gap between word lines, to resolve or improve upon a problem of a capacitance of the bit line increasing due to the shielding structure by sufficiently isolating the bit line and the shielding structure while controlling the coupling between the bit lines through a conductive shielding structure, and/or to realize a complex shielding structure through a wafer bonding.

A semiconductor memory device according to various example embodiments includes a peripheral gate structure on a substrate; a bit line on the peripheral gate structure, and extending in a second direction different from a first direction; a shielding structure on the peripheral gate structure, adjacent to the bit line, and extending in the second direction; a back gate electrode on the bit line and the shielding structure and extending in the first direction; a first word line on the bit line and the shielding structure, extending in the first direction and on one side of the back gate electrode in the second direction, and a second word line on the bit line and the shielding structure and on another side of the back gate electrode; and a first activation pattern \on the bit line and between the back gate electrode and the first word line and a second activation pattern between the back gate electrode and the second word line. The shielding structure includes a low-dielectric material.

Alternatively or additionally a semiconductor memory device according to various example embodiments includes a peripheral gate structure on a substrate; a bit line on the peripheral gate structure, and extending in a second direction different from a first direction; a shielding structure adjacent to the bit line on the peripheral gate structure and extending in the second direction; a back gate electrode on the bit line and the shielding structure and extending in the first direction; a first word line on the bit line and the shielding structure, extending in the first direction and on one side of the back gate electrode in the second direction, and a second word line on the bit line and the shielding structure and on another side of the back gate electrode; and a first activation pattern on the bit line between the back gate electrode and the first word line and a second activation pattern placed the back gate electrode and the second word line. The shielding structure has an air gap.

Alternatively or additionally a semiconductor memory device according to various example embodiments includes a peripheral gate structure on a substrate; a bit line on the peripheral gate structure, and extending in a second direction different from a first direction; a shielding structure adjacent to the bit line on the peripheral gate structure and extending in the second direction; a back gate electrode on the bit line and the shielding structure and extending in the first direction; a first word line extending in the first direction and on one side of the back gate electrode in the second direction, and a second word line placed on another side of the back gate electrode, the first and second word lines on the bit line and the shielding structure; and a first activation pattern between the back gate electrode and the first word line and a second activation pattern between the back gate electrode and the second word line, the first and second activation patterns on the bit line. The shielding structure includes a shielding pattern, and a shielding insulation layer placed between the shielding pattern and the bit line, the shielding pattern includes a conductive material, and the shielding insulation layer includes a low-dielectric material, and/or the shielding insulation layer has an air gap.

According to various example embodiments, the semiconductor memory device and/or the method for manufacturing the same may sufficiently prevent or reduce an amount of and/or an impact from a coupling between the bit lines without a conductive shielding structure by sufficiently isolating the bit lines while improving an integration by the interval between the word lines, may resolve or help or reduce a problem of the capacitance of the bit line increasing due to the shielding structure by sufficiently isolating the bit line and the shielding structure while controlling the coupling between the bit lines through a conductive shielding structure, and/or may realize a shielding structure of a complex structure through a wafer bonding.

### BRIEF DESCRIPTION OF THE DRAWINGS

FIG. 1 is a schematic layout diagram of a semiconductor memory device according to various example embodiments.

FIG. 2 is a top plan view of a cell array region in FIG. 1.

FIG. 3 is a cross-sectional view cut along lines A-A and B-B in FIG. 2.

FIG. 4 is a cross-sectional view cut along lines C-C and D-D in FIG. 2.

FIG. 5 is an enlarged cross-sectional view of a part P in FIG. 3.

FIG. 6 is an enlarged cross-sectional view of a part Q in FIG. 4.

FIG. 7 is an example view to explain how a word line in FIG. 2 is routed in a peripheral circuit region.

FIG. 8 to FIG. 10 are views to explain a semiconductor memory device according to various example embodiments and corresponding to FIG. 3, FIG. 4, and FIG. 6, respectively.

FIG. 11 to FIG. 13 are views to explain a semiconductor memory device according to various example embodiments and corresponding to FIG. 3, FIG. 4, and FIG. 6, respectively.

FIG. 14 to FIG. 16 are views to explain a semiconductor memory device according to various example embodiments and corresponding to FIG. 3, FIG. 4, and FIG. 6, respectively.

FIG. 17 to FIG. 19 are views to explain a semiconductor memory device according to various example embodiments and corresponding to FIG. 14 to FIG. 16, respectively.

FIG. 20 to FIG. 22 are views to explain a semiconductor memory device according to various example embodiments and corresponding to FIG. 14 to FIG. 16, respectively.

FIG. 23 and FIG. 24 are views to explain a semiconductor memory device according to various example embodiments and corresponding to FIG. 21 and FIG. 22, respectively.

FIG. 25 and FIG. 26 are views to explain a semiconductor memory device according to various example embodiments and corresponding to FIG. 21 and FIG. 22, respectively.

FIG. 27 to FIG. 98 are views to explain a method for manufacturing a semiconductor memory device according to various example embodiments.

FIG. 99 to FIG. 113 are views to explain a method for manufacturing a semiconductor memory device according to various example embodiments and corresponding to steps of FIG. 80 to FIG. 85.

### DETAILED DESCRIPTION

Hereinafter, various example embodiments will be described in detail with reference to the accompanying drawings so that those with ordinary skill in the art to which the present disclosure pertains may easily carry out various example embodiments. Inventive concepts may be implemented in various different ways and are not limited to example embodiments described herein.

In order to clarify example embodiments, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, example embodiments are not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

Additionally, throughout the specification, two directions that are parallel to an upper surface of a substrate and intersect with each other are defined as a first direction D1 and a second direction D2, respectively, and a direction perpendicular to the upper surface of the substrate is described as a third direction D3. For example, the first direction D1 and the second direction D2 may be orthogonal to each other.

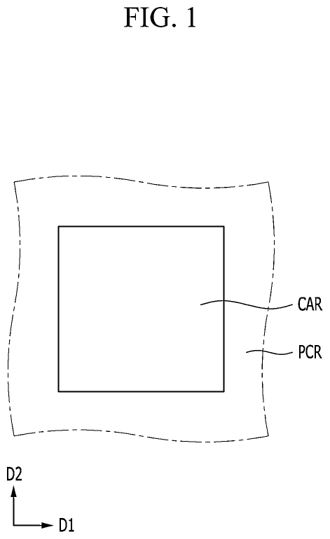

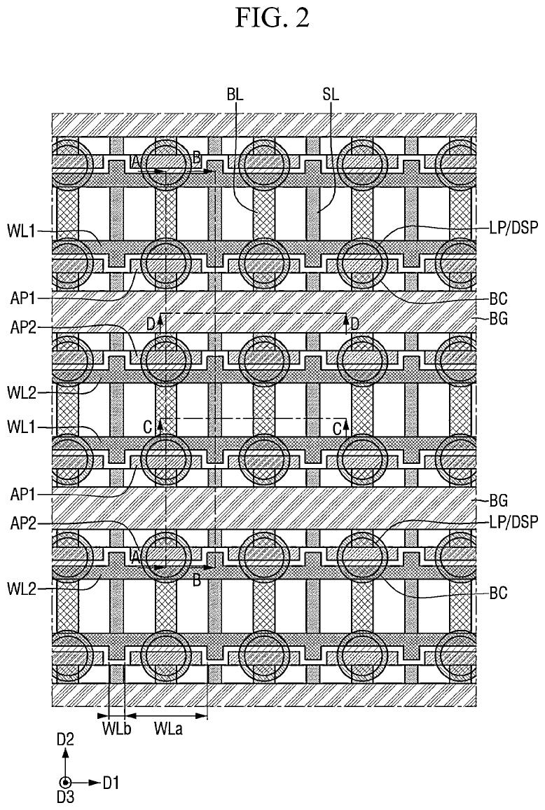

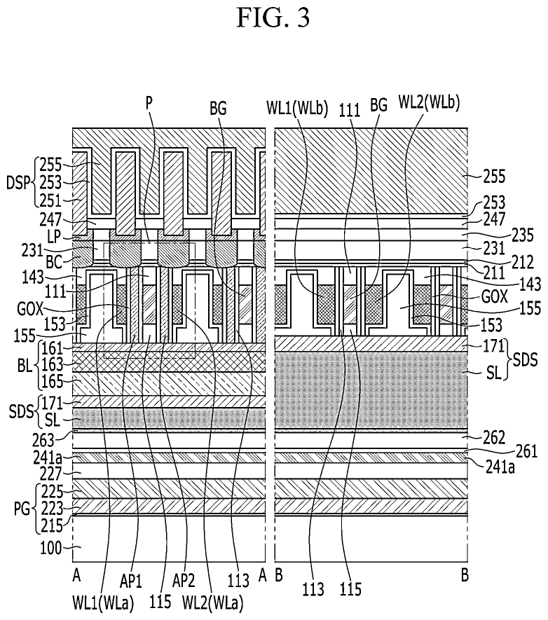

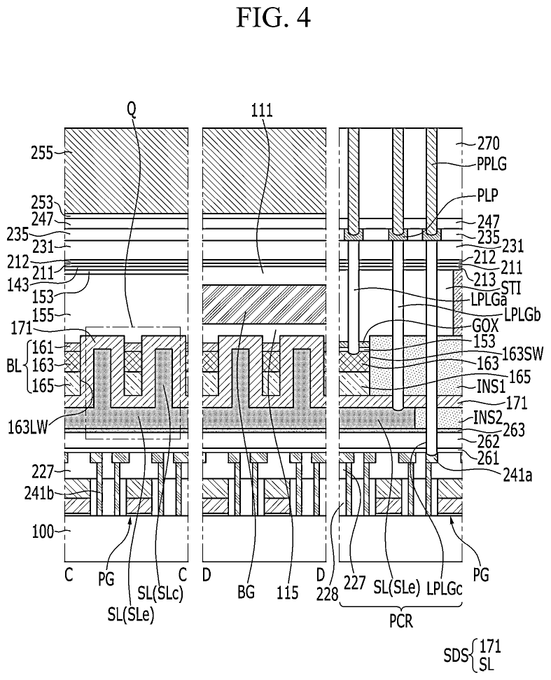

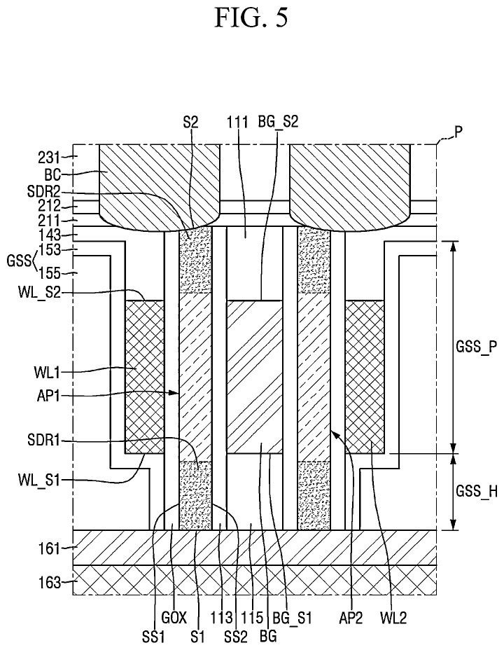

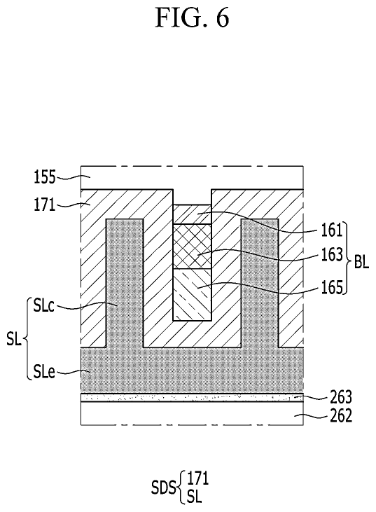

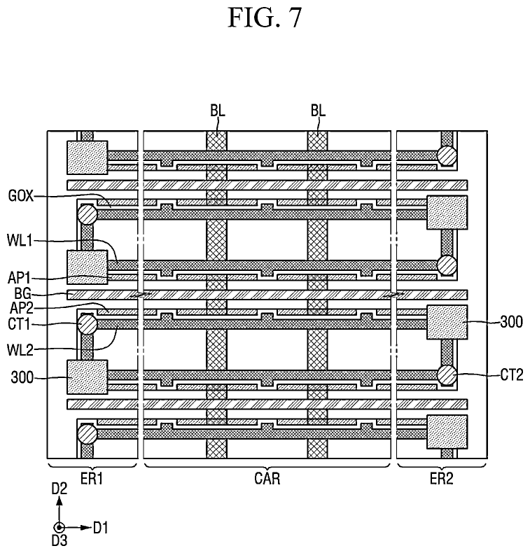

FIG. 1 is a schematic layout diagram of a semiconductor memory device according to various example embodiments. FIG. 2 is a top plan view of a cell array region in FIG. 1. FIG. 3 is a cross-sectional view cut along lines A-A and B-B in FIG. 2. FIG. 4 is a cross-sectional view cut along lines C-C and D-D in FIG. 2. FIG. 5 is an enlarged cross-sectional view of a part P in FIG. 3. FIG. 6 is an enlarged cross-sectional view of a part Q in FIG. 4. FIG. 7 is an example view to explain how a word line in FIG. 2 is routed in a peripheral circuit region. For reference, FIG. 4 includes a cross-section view of a peripheral circuit region bordering the cell array region in FIG. 1.

Semiconductor memory devices according to some example embodiments may include memory cells including a vertical channel transistor (VCT).

Referring to FIG. 1 to FIG. 7, the semiconductor memory device according to various example embodiments may include a peripheral gate structure PG, bit lines BL (e.g., column lines), word lines WL1 and WL2 (e.g., row lines), back gate electrodes BG, a shielding pattern SL, activation patterns AP1 and AP2, data storage patterns DSP.

The substrate 100 may include a cell array region CAR and a peripheral circuit region PCR. Memory cells may be arranged on the substrate 100 of the cell array region CAR.

The substrate 100 may be or include a silicon substrate, and/or may include other materials, for example, one or more of silicon germanium, indium antimony, lead tellurium compound, indium arsenic, indium phosphide, gallium arsenic or gallium antimony, but is not limited thereto. The substrate 100 may be doped, e.g., may be lightly doped; example embodiments are not limited thereto.

The peripheral gate structure PG may be placed on the substrate 100. The peripheral gate structure PG may be placed across the cell array region CAR and the peripheral circuit region PCR. For example, a part of the peripheral gate structure PG may be placed in the cell array region CAR of the substrate 100, and a remainder of the peripheral gate structure PG may be placed in the peripheral circuit region PCR of the substrate 100.

The peripheral gate structure PG may be included in one or more of a sensing transistor, transmission transistor, and driving transistor. For example, the peripheral gate structure PG included in the sensing transistor may be placed on the substrate 100 of the cell array region CAR, but is not limited to this. The types of the transistors of the peripheral circuit placed on the substrate 100 of the cell array region CAR may vary depending on the design arrangement of the semiconductor memory device.

The peripheral gate structure PG may include a peripheral gate insulating layer 215, a peripheral gate conductive pattern 223, and a peripheral gate mask pattern 225. The peripheral gate insulating layer 215 may include a silicon oxide layer, a silicon nitride layer, a high dielectric constant insulation layer having a higher dielectric constant than the silicon oxide layer, or a combination thereof. The high dielectric constant insulation layer may include, for example, a metal oxide, a metal oxynitride, a metal silicon oxide, a metal silicon oxynitride, or a combination thereof, but is not limited thereto,

The peripheral gate conductive pattern 223 may include a conducting material, for example, a doped semiconductor material such as but not limited to doped polysilicon, a conductive metal nitride, a conductive metal silicon nitride, a metal nitride, a conductive metal silicide, a conductive metal oxide, a two-dimensional material (a 2D material), a metal, or a combination thereof. The peripheral gate mask pattern 225 is made of an insulating material. In the semiconductor memory device according to some example embodiments, the two-dimensional material may be a metallic material and/or a semiconductor material. The two-dimensional material (2D material) may include a two-dimensional allotrope and/or a two-dimensional compound, for example, one or more of graphene, molybdenum disulfide (MoS₂), molybdenum diselenide (MoSe₂), tungsten diselenide (WSe₂), tungsten disulfide (WS₂), or combinations thereof, but is not limited thereto. For example, since the above-mentioned two-dimensional materials are listed only as examples, the two-dimensional materials that may be included in the semiconductor memory device of example embodiments may not limited to the above-mentioned materials.

The first peripheral lower insulation layer 227 and the second peripheral lower insulation layer 228 are disposed on the substrate 100. The first peripheral lower insulation layer 227 and the second peripheral lower insulation layer 228 may each be made of or comprise or consist of an insulating material such as the same or different insulating materials.

The peripheral wire line 241a and the peripheral contact plug 241b may be placed on the first peripheral lower insulation layer 227 and the second peripheral lower insulation layer 228. Although the peripheral wire line 241a and the peripheral contact plug 241b are shown as different layers, they are not limited thereto. The boundary between the peripheral wire line 241a and the peripheral contact plug 241b may be indistinguishable. The peripheral wire line 241a and the peripheral contact plug 241b each include a conducting material such as the same or different conducting materials.

The first peripheral upper insulation layer 261 and the second peripheral upper insulation layer 262 may be disposed on the peripheral wire line 241a and the peripheral contact plug 241b. The first peripheral upper insulation layer 261 and the second peripheral upper insulation layer 262 may each be made of an insulating material. Unlike what is shown, a peripheral upper insulation layer made of a single layer may be disposed on the peripheral wire line 241a and the peripheral contact plug 241b.

The bonding insulation layer 263 is disposed on the second peripheral upper insulation layer 262. The bonding insulation layer 263 may be used to join wafers, such as 300 mm wafers. The bonding insulation layer 263 may include, for example, silicon carbonitride (SiCN).

The bit lines BL are disposed on the peripheral gate structure PG. For example, the bit lines BL are placed on the bonding insulation layer 263. Additionally, the bit lines BL are disposed on a body portion SLe of a shielding pattern SL, which will be described later.

The bit line BL may extend along the second direction D2. The adjacent bit lines BL may be spaced apart in the first direction D1. The bit line BL includes a long side wall 163LW extending in the second direction D2 and a short side wall 163SW extending in the first direction D1.

Each bit line BL may be extended from the cell array region CAR to the peripheral circuit region PCR. The end of each bit line BL may be placed on the peripheral circuit region PCR. The first peripheral insulation layer INS1 may be placed on the side of the first direction D1 of the end of the bit line BL placed on the peripheral circuit region PCR.

Each bit line BL may include a bit line mask pattern 165, a metal pattern 163, and a polysilicon pattern 161 sequentially stacked in the third direction D3. Here, the bit line mask pattern 165 may be in contact with the body portion SDSe of a shielding structure SDS, which will be described later, in the third direction D3. Unlike what is shown, the bit line BL may include one of an undoped or doped polysilicon pattern 161 and a metal pattern 163.

The bit line BL may include a conductive bit line. The conductive bit line includes a layer made of a conductive material in the bit line BL. The conductive bit line may include an undoped or doped polysilicon pattern 161 and a metal pattern 163.

The metal pattern 163 may include a conductive material, for example, a conductive metal nitride, a conductive metal silicon nitride, a metal carbonitride, a conductive metal silicide, a conductive metal oxide, a two dimension material such as graphene and/or boron nitride (BN), a metal, or a combination thereof. The bit line mask pattern 165 may include an insulating material such as silicon nitride and/or silicon oxynitride.

In FIG. 4, the polysilicon pattern 161 among the bit line BLs is shown as not being placed in the peripheral circuit region PCR, but is not limited to this.

The shielding structure SDS is placed on the peripheral gate structure PG. The shielding structure SDS is disposed on the bonding insulation layer 263 and may be in contact with the bonding insulation layer 263.

The shielding structure SDS is placed adjacent to the bit line BL. In the cell array region CAR, the shielding structure SDS may be placed adjacent to the bit line BL in the first direction D1.

The shielding structure SDS may include a shielding pattern SL and a shielding insulation layer 171.

The shielding pattern SL may include a body portion SLe and an extending portion SLc. The body portion SLe of the shielding pattern SL may extend along the first direction D1 and the second direction D2, disposed between the shielding insulation layer 171 and the bonding insulation layer 263 in the third direction D3, and in contact with the upper surface of the bonding insulation layer 263. The extending portion SLc of the shielding pattern SL may be disposed on the body portion SLe of the shielding pattern SL in the third direction D3, disposed between the bit lines BL adjacent in the first direction D1, and extend in the second direction D2.

The shielding pattern SL may extend from the cell array region CAR to the peripheral circuit region PCR. For example, the end of the body portion SLe of the shielding pattern SL may be placed on the peripheral circuit region PCR. The second peripheral insulation layer INS2 may be placed on the side of the first direction D1 of the end of the shielding pattern SL placed on the peripheral circuit region PCR.

In FIG. 4, the shielding pattern SL is shown to include the body portion SLe and the extending portion SLc, but is not limited thereto. The shielding pattern SL may only include the extending portion SLc. In this case, the shielding pattern SL may be placed between the bit lines BL adjacent in the first direction D1.

The shielding insulation layer 171 may be disposed between the shielding pattern SL and the bit line BL. Explained differently, the shielding insulation layer 171 may be disposed on the upper surface of the shielding pattern SL of the third direction D3.

The shielding structure SDS may include low dielectric materials. Here, a dielectric constant of the low dielectric material may be lower than a dielectric constant of silicon oxide (SiO₂).

As an example, the low dielectric material may include a hydrocarbon compound, carbide, carbon, or a combination thereof. For example, the low dielectric material may be or may include charcoal and/or ash and may include various types of hydrocarbon compounds, carbide, carbon, or combinations thereof produced while carbon cyclic of hydrocarbon-based polymer is broken by a thermal decomposition by heat decomposing hydrocarbon-based polymer. For example, the hydrocarbon-based polymer may include aromatic hydrocarbon polymer, (meth)acryl-based polymer, vinyl pyridine polymer, vinyl ester polymer, vinylpyrrolidone polymer, olefin polymer, or a combination thereof.

The low dielectric material may include 60 wt % to 90 wt % of carbon and 10 wt % to 40 wt % of hydrogen based on the entire weight, for example, 70 wt % to 90 wt % of carbon and 10 wt % to 30 wt % of hydrogen, 72 wt % to 88 wt % of carbon and 12 wt % to 28 wt % of hydrogen, or 75 wt % to 85 wt % of carbon and 15 wt % to 25 wt % of hydrogen.

Alternatively or additionally, the low dielectric materials may further include addition components including halogen element, nitrogen (N), oxygen (O), fluorine (F), sulfur(S), phosphorus (P), sodium (Na), magnesium (Mg), manganese (Mn), silicon (Si), iron (Fe), or combinations thereof. The addition components may be derived from a composition element of hydrocarbon-based polymer used to form the low-dielectric material. The additional components may be included from 0 wt % to 10 wt % based on the entire weight of the low-dielectric material.

As an example, the low-dielectric material may include carbon doped silicon oxide (SiOC), or porous silicon oxide.

In the carbon doping silicon oxide, at least a part of the oxygen atom bonded to silicon in silicon oxide is substituted for an organic material group including carbon. For example, the carbon doped silicon oxide may be trimethylsilane (TMS) (BLACKDIAMONDTM), tetramethylcyclotetrasilane (TMCTS) (CoralTM), dimethyldimethoxysilane (DMDMOS) (AuroraTM), or hydrogen silsesoxoxane (HSG).

Porous silicon oxide may be formed by oxidizing carbon-doped silicon oxide and removing an organic material including carbon. For example, adding an oxidizing agent to carbon doped silicon oxide may oxidize the carbon doped silicon oxide to form silicon oxide (SiOₓ) and remove an organic material including carbon.

For example, the shielding pattern SL may include a conductive material, and the shielding insulation layer 171 may include a low-dielectric material. Accordingly, the semiconductor memory device may or may be more likely to sufficiently isolate between the bit line BL and the shielding structure SDS while controlling the coupling between the bit lines BL through the conductive shielding structure, thereby solving or helping to mitigate a problem of increasing the capacitance of the bit lines BL by the shielding structure SDS.

The conductive material included in the shielding pattern SL, for example, may include a conductive metal nitride, a conductive metal silicon nitride, a metal carbonitride, a conductive metal silicide, a conductive metal oxide, a 2D material, a metal, or a combination thereof.

In FIG. 4 and FIG. 6, the length of the third direction D3 of the extending portion SLc of the shielding pattern SL may be equal to or longer than the length of the third direction D3 of the metal pattern 163 of the bit line BL. Alternatively or additionally, the height of the third direction D3 of the lower end of the extending portion SLc of the shielding pattern SL may be equal to or lower than the height of the third direction D3 of the lower end of the metal pattern 163 of the bit line BL, and the height of the third direction D3 of the upper end of the extending portion SLc of the shielding pattern SL may be equal to or higher than the height of the third direction D3 of the upper end of the metal pattern 163 of the bit line BL. For example, the extending portion SLc of the shielding pattern SL may extends in the third direction D3 and overlap with the metal pattern 163 of the bit line BL in the first direction D1. Accordingly, the semiconductor memory device may control or help control the coupling between the bit lines BL through the shielding structure SDS.

The first activation patterns AP1 and the second activation patterns AP2 may be placed on each bit line BL. The first activation patterns AP1 and the second activation patterns AP2 may be arranged alternately along the second direction D2.

The first activation patterns AP1 may be separated from each other in the first direction D1. The first activation patterns AP1 may be spaced out with a regular interval. The second activation patterns AP2 may be separated from each other in the first direction D1. The second activation patterns AP2 may be spaced out with a regular interval. The first and second activation patterns AP1 and AP2 may be arranged two-dimensionally along the first direction D1 and the second direction D2 that intersect each other.

For example, the first activation pattern AP1 and the second activation pattern AP2 may each be made of a monocrystalline semiconductor material. As an example, the first activation pattern AP1 and the second activation pattern AP2 may each be made of monocrystalline silicon, and may be doped or undoped.

The first activation pattern AP1 and the second activation pattern AP2 may each have the length in the first direction D1, the width in the second direction D2, and the height in the third direction D3. The first activation pattern AP1 and the second activation pattern AP2 may each have a substantially uniform width. For example, the first activation pattern AP1 and the second activation pattern AP2 may each have substantially equivalent widths on the first and second surfaces S1 and S2. Additionally, the width of the first activation pattern AP1 may be the same as the width of the second activation pattern AP2.

The width of the first activation pattern AP1 and the width of second activation pattern AP2 may range from several nm to tens of nm. For example, the width of the first activation pattern AP1 and the width of the second activation pattern AP2 may range from 1 nm to 30 nm, more preferably, from 1 nm to 10 nm, but is not limited thereto. The length of each of the first and second activation patterns AP1 and AP2 may be larger than the line width of the bit line BL. For example, the length of each of the first and second activation patterns AP1 and AP2 may be larger than the width of the bit line BL in the first direction D1.

In FIG. 5, each of the first activation pattern AP1 and the second activation pattern AP2 includes a first surface S1 and a second surface S2 facing each other in the third direction D3. For example, the first surfaces S1 of the first and second activation patterns AP1 and AP2 may be in contact with the polysilicon pattern 161 of the bit line BL. Contrary to what is shown, if the polysilicon pattern 161 is omitted, the first surfaces S1 of the first and second activation patterns AP1 and AP2 may be in contact with (e.g., in direct contact with) the metal pattern 163.

Each of the first activation pattern AP1 and the second activation pattern AP2 may include a first sidewall SS1 and a second sidewall SS2 facing each other in the second direction D2. The second sidewall SS2 of the first activation pattern AP1 may face the first sidewall SS1 of the second activation pattern AP2.

The first sidewall SS1 of the first activation pattern AP1 may be adjacent to the first word line WL1. The second sidewall SS2 of the second activation pattern AP2 may be adjacent to the second word line WL2.

Each of the first activation pattern AP1 and the second activation pattern AP2 may include a first dopant region SDR1 adjacent to the bit line BL and a second dopant region SDR2 adjacent to the contact pattern BC. Each of the first activation pattern AP1 and the second activation pattern AP2 may include a channel region between the first dopant region SDR1 and the second dopant region SDR2. The first and second dopant regions SDR1 and SDR2 are regions where a dopant is incorporated within the first and second activation patterns AP1 and AP2. The impurity concentration within the first and second dopant regions SDR1 and SDR2 may be greater than (e.g., much greater than or more than several orders of magnitude greater than) the impurity concentration of the channel region of the first and second activation pattern AP1 and AP2. In some example embodiments, a conductivity type of dopants included in the first and second activation pattern AP1 and AP2 may be the same as, or opposite to, a conductivity type of impurities included in the first and second dopant regions SDR1 and SDR2.

Unlike what is shown, each of the first activation pattern AP1 and the second activation pattern AP2 may not include at least one of the first dopant region SDR1 and the second dopant region SDR2.

When operating the semiconductor memory device, the channel region of the first and second activation patterns AP1 and AP2 may be controlled by the first and second word lines WL1 and WL2 and the back gate electrodes BG. Since the first and second activation patterns AP1 and AP2 are made of or include monocrystalline semiconductor material, a leakage current characteristic of the semiconductor memory device may be improved.

The semiconductor memory device according to some example embodiments may further include an inserted semiconductor pattern disposed between the first activation pattern AP1 and the metal pattern 163, and the second activation pattern AP2 and the metal pattern 163.

The inserted semiconductor pattern may include semiconductor materials different from the first and second activation patterns AP1 and AP2. If the first and second activation patterns AP1 and AP2 include silicon such as monocrystalline silicon, the inserted semiconductor pattern may include silicon germanium such as monocrystalline silicon germanium, but is not limited thereto. By inserting the inserted semiconductor pattern, a floating body effect may be improved. The inserted semiconductor pattern between the first activation pattern AP1 and the metal pattern 163 may be spaced apart from the inserted semiconductor pattern between the second activation pattern AP2 and the metal pattern 163 in the second direction D2.

The back gate electrodes BG may be placed on the bit line BL and the shielding pattern SL. The back gate electrodes BG may be spaced apart from each other in the second direction D2. The back gate electrodes BG may be spaced apart with a regular interval. Each back gate electrode BG may extend in the first direction D1 across the bit line BL.

Each back gate electrode BG may be placed between the first activation pattern AP1 and the second activation pattern AP2, which are adjacent to each other in the second direction D2. For example, the first activation pattern AP1 may be placed on one side in the second direction D2 of each back gate electrode BG, and the second activation pattern AP2 may be placed on the other side in the second direction D2 of each back gate electrode BG. The height of the back gate electrode BG in the third direction D3 may be smaller than the height of the first and second activation patterns AP1 and AP2.

Each back gate electrode BG may be placed between the second sidewall SS2 of the first activation pattern AP1 and the first sidewall SS1 of the second activation pattern AP2. Each back gate electrode BG may be placed on the second sidewall SS2 of the first activation pattern AP1 and the first sidewall SS1 of the second activation pattern AP2.

The first activation pattern AP1 may be placed between the first word line WL1 and the back gate electrode BG. The second activation pattern AP2 may be placed between the second word line WL2 and the back gate electrode BG. Between the back gate electrodes BG adjacent in the second direction D2, a pair of first and second word lines WL1 and WL2 may be placed.

The back gate electrode BG may include a first surface BG_S1 and a second surface BG_S2 facing in the third direction D3. The first surface BG_S1 of the back gate electrode is closer to the bit line BL than the second surface BG_S2 of the back gate electrode.

The back gate electrode BG may include a conducting material, for example, a doped polysilicon, a conductive metal nitride, a conductive metal silicon nitride, a metal carbonitride, a conductive metal silicide, a conductive metal oxide, a 2D material, a metal, or a combination thereof. When the semiconductor memory device operates, a voltage is applied to the back gate electrode BG, so the threshold voltage of the vertical channel transistor may be adjusted. By adjusting the threshold voltage of the vertical channel transistor, the leakage current characteristic may be prevented from or reduced in likelihood of and/or impact from being deteriorated.

The back gate separation pattern 111 may be placed between the adjacent first activation pattern AP1 and second activation pattern AP2 in the second direction D2. The back gate separation pattern 111 may extend parallel to the back gate electrode BG in the first direction D1. The back gate separation pattern 111 may be disposed on the second surface BG_S2 of the back gate electrode.

The back gate separation pattern 111 may include, for example, a silicon oxide layer, a silicon oxynitride layer, or a silicon nitride. The back gate separation pattern 111 may be formed at the same level as a gate capping pattern 143, which will be explained later. In some cases, being at “the same level” may indicate being formed by the same manufacturing process; example embodiments are not limited thereto. The back gate separation pattern 111 may be formed of the same material as the gate capping pattern 143.

The back gate insulating pattern 113 may be placed between the back gate electrode BG and the first activation pattern AP1 and between the back gate electrode BG and the second activation pattern AP2. The back gate insulating pattern 113 may be placed between the back gate separation pattern 111 and the first activation pattern AP1 and between the back gate separation pattern 111 and the second activation pattern AP2. The back gate insulating pattern 113 may include, for example, a silicon oxide layer, a silicon oxynitride layer, a high dielectric constant insulation layer having a higher dielectric constant than the silicon oxide layer, or a combination thereof.

The back gate capping pattern 115 may be placed between the bit line BL and the back gate electrode BG. The back gate capping pattern 115 may be placed between the first activation pattern AP1 and the second activation pattern AP2 adjacent in the second direction D2. The back gate capping pattern 115 may be extended parallel to the back gate electrode BG in the first direction D1. The back gate capping pattern 115 may be placed on the first surface BG_S1 of the back gate electrode. The thickness of the back gate capping pattern 115 between the bit lines BL may be different from (e.g., greater than or less than) the thickness of the back gate capping pattern 115 on the bit line BL.

The back gate capping pattern 115 may be formed of an insulating material. The back gate capping pattern 115, for example, may include silicon oxide layer, silicon oxynitride layer, a silicon nitride layer, or combinations thereof.

The first word line WL1 and the second word line WL2 may be placed on the bit line BL and the shielding pattern SL. Each of the first word line WL1 and the second word line WL2 may extend along the first direction D1. The first word line WL1 and the second word line WL2 may be alternately arranged in the second direction D2.

The first word line WL1 may be placed on the first sidewall SS1 of the first activation patterns AP1. The second word line WL2 may be placed on the second sidewall SS2 of the second activation patterns AP2. The first activation patterns AP1 and the second activation patterns AP2 may be disposed between the first word line WL1 and the second word line WL2 adjacent in the second direction D2.

The first word line WL1 and the second word line WL2 may be spaced apart from the bit line BL and the contact pattern BC in the third direction D3. The first word line WL1 and the second word line WL2 may be placed between the bit line BL and the contact pattern BC.

Each of the first word line WL1 and the second word line WL2 may have a width in the second direction D2. The width of the first word line WL1 and the width of the second word line WL2 on the bit line BL may or may not be the same as each other, and may be different from the width of the first word line WL1 and the width of the second word line WL2 on the shielding pattern SL.

For example, each of the first word line WL1 and the second word line WL2 may include a first portion WLa of the word line and a second portion WLb of the word line. The width of the first portion WLa of the word line in the second direction D2 may be smaller than the width of the second portion WLb of the word line in the second direction D2. As an example, the first portion WLa of the word line may be placed on the bit line BL. The second portion WLb of the word line may be placed on the shielding pattern SL.

Each of the first word line WL1 and second word line WL2 may include a first portion WLa of the word line and a second portion WLb of the word line alternately arranged along the first direction D1. In the first word line WL1, each first activation pattern AP1 may be placed between the second portions WLb of the word lines adjacent in the first direction D1. In the second word line WL2, each second activation pattern AP2 may be placed between the second portions WLb of the word lines adjacent in the first direction D1.

The first word line WL1 and the second word line WL2 may include a first surface WL_S1 and a second surface WL_S2 facing in the third direction D3. The first surface WL_S1 of the first and second word lines is closer to the bit line BL than the second surface WL_S2 of the first and second word lines.

This is explained using the first word line WL1 as a nonlimiting example. For example, the height of the first word line WL1 in the third direction D3 may be the same as the height of the back gate electrode BG in the third direction D3. As another nonlimiting example, the height of the first word line WL1 in the third direction D3 may be greater than the height of the back gate electrode BG in the third direction D3. As another nonlimiting example, the height of the first word line WL1 in the third direction D3 may be smaller than the height of the back gate electrode BG in the third direction D3.

Additionally or alternatively, as a nonlimiting example, using the bit line BL as a reference, the height of the first surface WL_S1 of the first word line may be the same as the height of the first surface BG_S1 of the back gate electrode. As another nonlimiting example, the first surface WL_S1 of the first word line may be higher than the first surface BG_S1 of the back gate electrode. As another nonlimiting example, the first surface WL_S1 of the first word line may be lower than the first surface BG_S1 of the back gate electrode.

Additionally or alternatively, as a nonlimiting example, using the bit line BL as a reference, the height of the second surface WL_S2 of the first word line may be the same as the height of the second surface BG_S2 of the back gate electrode. As another nonlimiting example, the second surface WL_S2 of the first word line may be higher than the second surface BG_S2 of the back gate electrode. As another nonlimiting example, the second surface WL_S2 of the first word line may be lower than the second surface BG_S2 of the back gate electrode.

The first and second word lines WL1 and WL2 may independently or concurrently include a conducting material, for example, a doped polysilicon, a conductive metal nitride, a conductive metal silicon nitride, a metal carbonitride, a conductive metal silicide, a conductive metal oxide, a 2D material, a metal, or a combination thereof.

In some examples, the first surfaces WL_S1 of the first and second word lines WL1 and WL2 can have various forms. As a nonlimiting example, the first surfaces WL_S1 of the first and second word lines WL1 and WL2 may be rounded concavely. The first and second word lines WL1 and WL2 may each have a spacer form. In other words, the first surfaces WL_S1 of the first and second word lines WL1 and WL2 can be rounded convexly.

Additionally or alternatively, on the cross-section cut in the second direction D2, the second surface WL_S2 of the first and second word lines WL1 and WL2 may have a concave curved surface or may be flat. Additionally or alternatively, the first surface BG_S1 of the back gate electrode may have a concave curved surface or may be flat. Additionally or alternatively, the second surface BG_S2 of the back gate electrode may have a concave curved surface or may be flat. Example embodiments are not limited to this, and one of the first surface BG_S1 of the back gate electrode and the second surface BG_S2 of the back gate electrode may be flat.

The gate insulating patterns GOX may be placed between the first word line WL1 and the first activation pattern AP1, and between the second word line WL2 and the second activation patterns AP2. The gate insulating patterns GOX may be extended parallel to the first and second word lines WL1 and WL2 in the first direction D1.

The gate insulating pattern GOX may include a silicon oxide layer, a silicon oxynitride layer, a high dielectric constant insulation layer having a higher dielectric constant than the silicon oxide layer, or a combination thereof.

The gate insulating pattern GOX mat extend along the first sidewall SS1 of the first activation pattern AP1 and the second sidewall SS2 of the second activation pattern AP2. In the semiconductor memory devices according to various example embodiments, from a cross-sectional perspective, the gate insulating pattern GOX between the first activation pattern AP1 and the first word line WL1 may be separated from the gate insulating pattern GOX between the second activation pattern AP2 and the second word line WL2.

The gate capping pattern 143 may be placed between the first word line WL1 and the contact pattern BC and between the second word line WL2 and the contact pattern BC. The gate capping pattern 143 may cover the second surface WL_S2 of the first and second word lines WL1 and WL2.

A gate separation pattern GSS may be placed on the bit line BL. The gate separation pattern GSS may be placed between the bit line BL and the contact pattern BC. The gate separation pattern GSS may be in contact with the bit line BL.

The gate separation pattern GSS may be placed between the first word line WL1 and the second word line WL2 adjacent in the second direction D2. The first word line WL1 and the second word line WL2 may be separated by the gate separation pattern GSS. The gate separation pattern GSS may extend along the first direction D1 between the first word line WL1 and the second word line WL2.

The first word line WL1 may be placed between the gate separation pattern GSS and the first activation pattern AP1. The second word line WL2 may be placed between the gate separation pattern GSS and the second activation pattern AP2.

The gate separation pattern GSS may include a horizontal portion GSS_H and a protruding portion GSS_P. The protruding portion GSS_P of the gate separation pattern may protrude from the horizontal portion GSS_H of the gate separation pattern in the third direction D3.

The horizontal portion GSS_H of the gate separation pattern may be closer to the bit line BL than the protruding portion GSS_P of the gate separation pattern. The horizontal portion GSS_H of the gate separation pattern may be in contact with the bit line BL. The width of the horizontal portion GSS_H of the gate separation pattern in the second direction D2 is larger than the width of the protruding portion GSS_P of the gate separation pattern in the second direction D2.

The protruding portion GSS_P of the gate separation pattern may be placed between the sidewall of the first word line WL1 and the sidewall of the second word line WL2 facing to each other. The horizontal portion GSS_H of the gate separation pattern may cover the first surface WL_S1 of the first and second word lines WL1 and WL2.

The first word line WL1 and the second word line WL2 may be placed on the horizontal portion GSS_H of the gate separation pattern. The first word line WL1 and the second word line WL2 may ride on the horizontal portion GSS_H of the gate separation pattern. The first word line WL1 and the second word line WL2 may be placed between the horizontal portion GSS_H of the gate separation pattern and the contact pattern BC.

The gate separation pattern GSS may include a gate separation liner 153 and a gate separation filling layer 155. The gate separation liner 153 may extend along the first surface WL_S1 of the first and second word lines WL1 and WL2 and the sidewall of the first and second word lines WL1 and WL2. The gate separation liner 153 may be in contact with the gate insulating pattern GOX. The gate separation liner 153 and the gate separation filling layer 155 may each be made of an insulating material. Unlike what is shown, the gate separation pattern GSS may be a single layer.

In FIG. 7, the first and second word lines WL1 and WL2 and the back gate electrodes BG may be extended to the first and second edge regions ER1 and ER2 in the cell array region CAR. The first edge region ER1 and the second edge region ER2 may be included in the peripheral circuit region PCR.

The first and second word lines WL1 and WL2 may each include a line portion extending in the first direction D1 and a protruding portion extending in the second direction D2 and connected to the line portion. For example, the protruding portion of the first word line WL1 may be placed in the second edge region ER2, and the protruding portion of the second word line WL2 may be placed in the first edge region ER1.

Furthermore, separation insulating patterns 300 may be placed in the first and second edge regions ER1 and ER2, respectively. The separation insulating pattern 300 may vertically penetrate the first and second word lines WL1 and WL2 in the first and second edge regions ER1 and ER2, respectively. The first and second word lines WL1 and WL2 may be electrically separated from each other by the separation insulating patterns 300 in the first and second edge regions ER1 and ER2.

In the first edge region ER1, the first word line contact plug CT1 may be connected to the second word line WL2. In the second edge region ER2, the second word line contact plug CT2 may be connected to the first word line WL1.

The arrangement of the first word line contact plug CT1 and the second word line contact plug CT2 is only an example for the explanation, and example embodiments are not limited to this.

Additionally or alternatively, the separation method of the first word line WL1 and the second word line WL2 shown in FIG. 7 is only an example method, and the technical idea of the present disclosure is not limited to this.

The contact patterns BC may penetrate the contact interlayer insulating layer 231 and the contact etch stopping layers 211 and 212. The contact patterns BC may be connected to the first and second activation patterns AP1 and AP2, respectively. The contact patterns BC may be connected to the second surface S2 of the first and second activation patterns AP1 and AP2. Each contact pattern BC may have the same or different various shapes, such as circular, oval, rectangular, square, rhombus, or hexagon, from a two-dimensional perspective.

The contact pattern BC may include a conducting material, for example, a doped polysilicon, a conductive metal nitride, a conductive metal silicon nitride, a metal carbonitride, a conductive metal silicide, a conductive metal oxide, a 2D material, a metal, or a combination thereof.

The contact etch stopping layers 211 and 212 may include a lower contact etch stopping layer 211 and an upper contact etch stopping layer 212. The lower contact etch stopping layer 211 and the upper contact etch stopping layer 212 may be accumulated sequentially on the gate capping pattern 143 and the back gate separation pattern 111. Unlike shown, the contact etch stopping layer may be a single layer. The contact interlayer insulating layer 231, the lower contact etch stopping layer 211, and the upper contact etch stopping layer 212 may each be made of an insulating material.

In some example embodiments, the lower contact etch stopping layer 211 and the upper contact etch stopping layer 212 may not be placed on the gate capping pattern 143 and the back gate separation pattern 111. As an example, the contact pattern BC may be formed in an embossed manner. For example, a contact layer is formed on the gate capping pattern 143, the back gate separation pattern 111, and the second surface S2 of the first and second activation patterns AP1 and AP2. After this, the contact layer may be patterned to form a contact pattern BC. A contact separation pattern 232 is formed between the separated contact patterns BC. The contact separation pattern 232 may be made of an insulating material. Also, the contact pattern BC may include a lower contact pattern and an upper contact pattern. The lower contact pattern is in contact with the first and second activation patterns AP1 and AP2. The upper contact pattern is placed on the lower contact pattern. The concentration of an impurity included in the lower contact pattern may be greater than the concentration of an impurity included in the upper contact pattern.

Landing pads LP may be placed on the contact pattern BC. From a two-dimensional perspective, the landing pads LP may have various shapes such as circular, oval, rectangular, square, rhombus, and hexagon.

The pad separation insulating patterns 245 may be placed between the landing pads LP. From a two-dimensional perspective, the landing pads LP may be arranged in a matrix format along the first direction D1 and the second direction D2. The upper surface of the landing pad LP may be substantially coplanar with the upper surface of the pad separation insulating pattern 245.

The landing pad LP may include a conducting material, for example, a doped polysilicon, a conductive metal nitride, a conductive metal silicon nitride, a metal carbonitride, a conductive metal silicide, a conductive metal oxide, a 2D material, a metal, or a combination thereof.

The data storage patterns DSP may be placed respectively on the landing pads LP. The data storage patterns DSP may be electrically connected to the first and second activation patterns AP1 and AP2, respectively. The data storage patterns DSP, as shown in FIG. 2, may be arranged in a matrix format along the first direction D1 and the second direction D2. The data storage patterns DSP may be completely overlapped or partially overlapped with the landing pads LP in the third direction D3. The data storage patterns DSP may be in contact with the entire or part of the upper surface of the landing pad LP.

As an example, the data storage patterns DSP may be or may include a capacitor. The data storage patterns DSP may include a capacitor dielectric layer 253 interposed between the storage electrodes 251 and the plate electrode 255. In this case, the storage electrode 251 may be in contact with the landing pad LP. From a two-dimensional perspective, the storage electrode 251 may have various shapes such as circular, oval, rectangular, square, rhombus shape, and hexagon. The data storage patterns DSP may completely or partially overlap the landing pads LP. The data storage patterns DSP may be in contact with the entire or part of the upper surface of the landing pad LP. The storage electrodes 251 may penetrate the upper etch stopping layer 247. The upper etch stopping layer 247 may be made of an insulating material.

Alternatively or additionally, the data storage patterns DSP may be or may include a variable resistor pattern that may be switched between two resistance states by electrical pulses applied to a memory element. For example, the data storage patterns DSP may include phase-change materials whose crystal state changes depending on an amount of a current, perovskite compounds, transition metal oxide, and magnetic materials, ferromagnetic materials, or antiferromagnetic materials.

Although not shown, a memory cell contact plug PLG connected to the plate electrode 255 may be placed on the data storage patterns DSP.

The lower peripheral contact plugs LPLGa, LPLGb, and LPLGc penetrate an isolation layer STI. The lower peripheral contact plugs LPLGa, LPLGb, and LPLGc may be connected to the metal pattern 163, the end of the shielding pattern SL, and the peripheral wire line 241a, which are placed at the end of the bit line BL.

The contact plug pads PLP may be placed on the lower peripheral contact plugs LPLGa, LPLGb, and LPLGc. The pad separation insulating patterns 245 may be placed between the contact plug pads PLP.

The upper peripheral contact plugs PPLG penetrate the upper interlayer insulating layer 270 and the upper etch stopping layer 247. The upper peripheral contact plugs PPLG may be placed on the contact plug pads PLP. The upper peripheral contact plugs PPLG may be connected to the contact plug pad PLP.

The lower peripheral contact plugs LPLGa, LPLGb, and LPLGc, the contact plug pads PLP, and the upper peripheral contact plugs PPLG may include a conducting material, respectively, for example, a doped polysilicon, a conductive metal nitride, a conductive metal silicon nitride, a metal carbonitride, a conductive metal silicide, a conductive metal oxide, a 2D material, a metal, or a combination thereof.

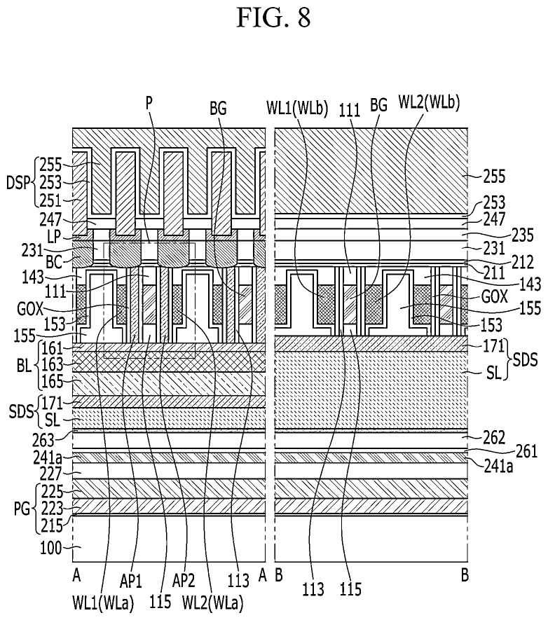

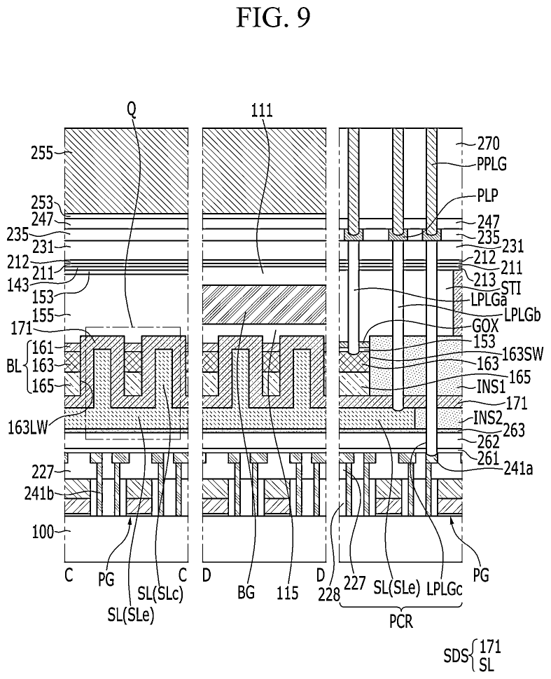

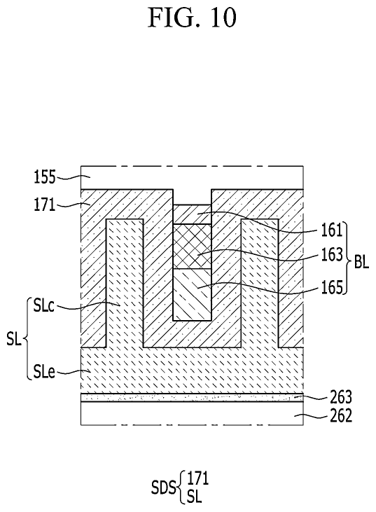

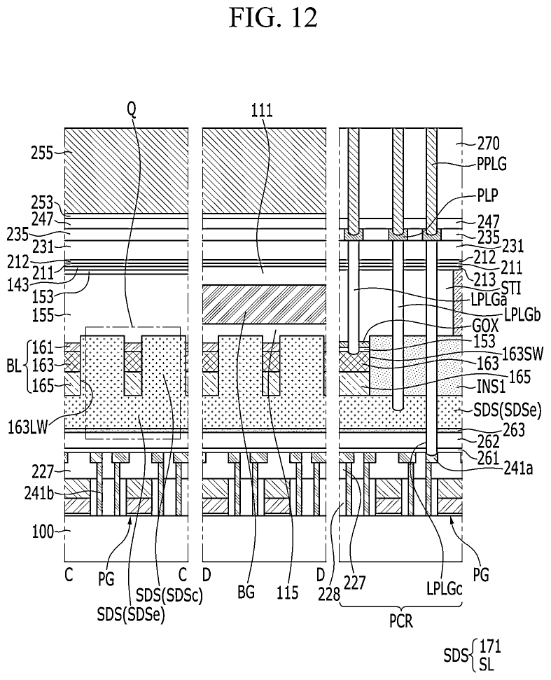

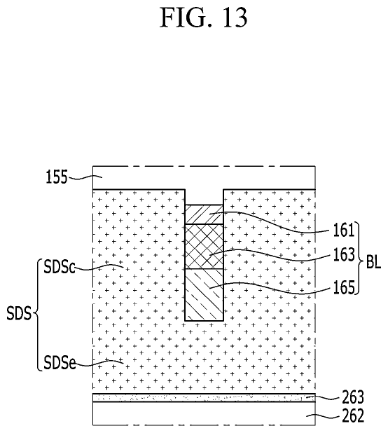

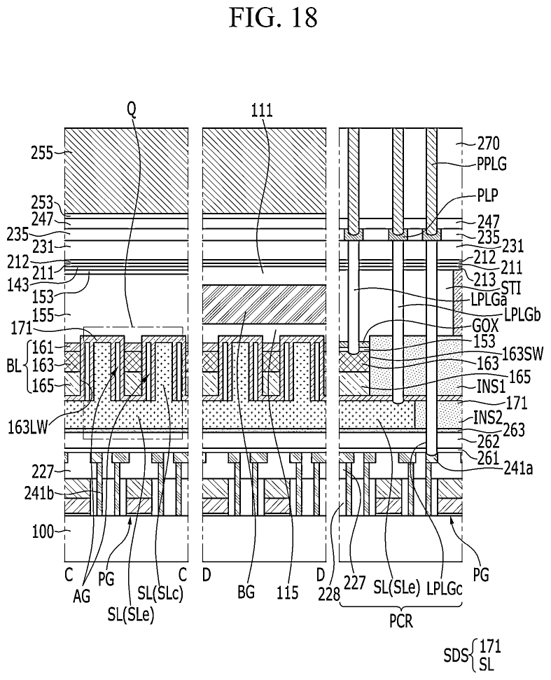

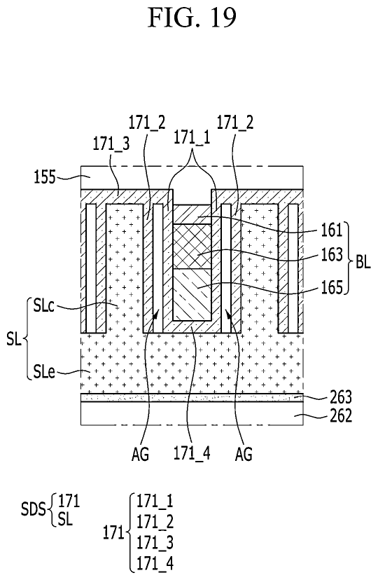

FIG. 8 to FIG. 26 are views to explain a semiconductor memory device according to other embodiments. For better understanding and ease of description, an explanation will focus on differences from what was explained with reference to FIG. 1 to FIG. 7.

FIG. 8 to FIG. 13 are views to explain a semiconductor memory device according to other embodiments and corresponding to FIG. 3, FIG. 4, and FIG. 6, respectively.

Referring to FIG. 8 to FIG. 10, the shielding structure SDS of the semiconductor memory device according to some example embodiments may include a low-dielectric material. Here, a dielectric constant of the low-dielectric material may be lower than a dielectric constant of silicon oxide (SiO₂).

In FIG. 8 to FIG. 10, the shielding structure SDS may include a shielding pattern SL and a shielding insulation layer 171.

The shielding pattern SL may include a body portion SLe and an extending portion SLc. The body portion SLe of the shielding pattern SL may extend along the first direction D1 and the second direction D2, be disposed between the shielding insulation layer 171 and the bonding insulation layer 263 in the third direction D3, and be in contact with the upper surface of the bonding insulation layer 263. The extending portion SLc of the shielding pattern SL may be disposed on the body portion SLe of the shielding pattern SL in the third direction D3, be disposed between the adjacent bit lines BL in the first direction D1, and extend along the second direction D2.

The shielding insulation layer 171 may be disposed between the shielding pattern SL and the bit line BL. For example, the shielding insulation layer 171 may be disposed on the upper surface of the shielding pattern SL in the third direction D3.

As a nonlimiting example, the shielding pattern SL includes a low-dielectric material, and the shielding insulation layer 171 includes an insulating material. Accordingly, the semiconductor memory device may improve an integration as the gap between the word lines WL1 and WL2 is reduced by including the back gate electrode BG, and sufficiently isolates the bit lines BL by including a low-dielectric material, thereby preventing or reducing a large coupling between the bit lines BL without a conductive shielding structure.

The low-dielectric material included in the shielding pattern SL may include, for example, a hydrocarbon compound, carbide, carbon, or a combination thereof, or the low-dielectric material included in the shielding pattern SL includes, for example, carbon doped silicon oxide (SiOC), or porous silicon oxide. Since the shielding pattern SL does not include a conductive material, no voltage is applied, so the lower peripheral contact plug LPLGb connected to the shielding pattern SL in the peripheral circuit region PCR may be omitted.

The insulating material included in the shielding insulation layer 171 may include, for example, a silicon oxide layer, a silicon oxynitride layer, a silicon nitride, or a combination thereof.

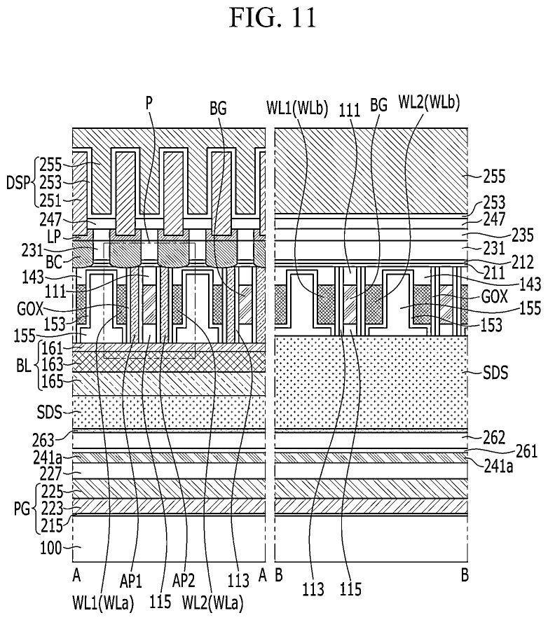

In FIG. 11 to FIG. 13, the shielding structure SDS includes a low-dielectric material. The shielding structure SDS, in FIG. 3, FIG. 4, and FIG. 6, may only include the shielding pattern SL, and not include the shielding insulation layer 171. Alternatively, both the shielding pattern SL and the shielding insulation layer 171 of the shielding structure SDS may include a low-dielectric material. In this case, as shown in FIG. 11 to FIG. 13, the boundary between the shielding pattern SL and the shielding insulation layer 171 may not be distinguished. Accordingly, the semiconductor memory device improves an integration as the gap between the word lines WL1 and WL2 is reduced by including the back gate electrode BG, and sufficiently isolates the bit lines BL by including a low-dielectric material, thereby preventing or reducing a large coupling between the bit lines BL without a conductive shielding structure.

The shielding structure SDS may include a body portion SDSe and an extending portion SDSc. The body portion SDSe of the shielding structure SDS may extend along the first direction D1 and the second direction D2. In other words, the body portion SDSe of the shielding structure SDS may have a plate or sheet shape. The body portion SDSe of the shielding structure SDS may be disposed between the bit line BL and the bonding insulation layer 263 in the third direction D3, and in contact with the upper surface of the bonding insulation layer 263 and the bottom surface of the bit line BL, respectively. The extending portion SDSc of the shielding structure SDS may be placed on the body portion SDSe of the shielding structure SDS in the third direction D3. The extending portion SDSc of the shielding structure SDS is placed between the bit lines BL adjacent in the first direction D1. The extending portion SDSc of the shielding structure SDS may extend along the second direction D2. The side of the extending portion SDSc of the shielding structure SDS in the first direction D1 may be in contact with the side of the bit line BL.

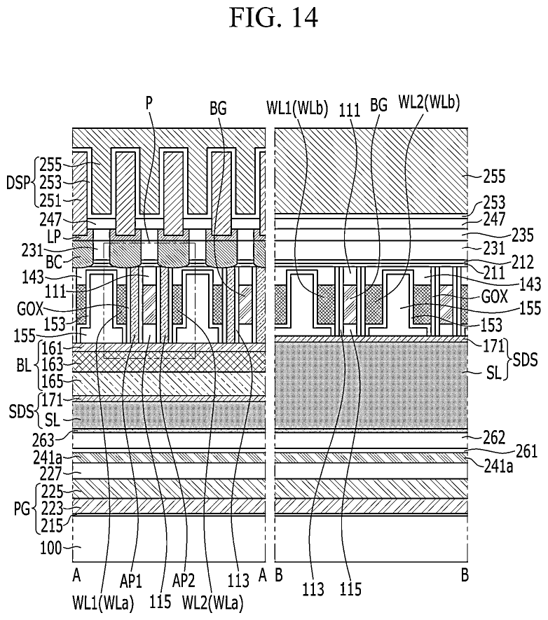

Referring to FIG. 14 to FIG. 26, the shielding structure SDS of the semiconductor memory device according to some example embodiments may include an air gap AG.

FIG. 14 to FIG. 16 are views to explain a semiconductor memory device according to various example embodiments and corresponding to FIG. 3, FIG. 4, and FIG. 6, respectively.

In FIG. 14 to FIG. 16, the shielding structure SDS may include a shielding pattern SL and a shielding insulation layer 171.

The shielding pattern SL may include a body portion SLe and an extending portion SLc. The body portion SLe of the shielding pattern SL may extend along the first direction D1 and the second direction D2, be placed between the shielding insulation layer 171 and the bonding insulation layer 263 in the third direction D3, and be in contact with the bonding insulation layer 263. The extending portion SLc of the shielding pattern SL may be placed on the body portion SLe of the shielding pattern SL in the third direction D3, be disposed between the bit lines BL adjacent in the first direction D1, and extend along the second direction D2.

The shielding insulation layer 171 may be disposed between the shielding pattern SL and the bit line BL. For example, the shielding insulation layer 171 may be disposed on the upper surface of the shielding pattern SL in the third direction D3.

As an example, the shielding insulation layer 171 may have an air gap AG. The air gap AG may be filled with air such as clean, dry air, or may be in a vacuum state.

The air gap AG may be placed on the body portion SLe of the shielding pattern SL in the third direction D3, be placed adjacent to the bit line BL in the first direction D1, and extend along the second direction D2.

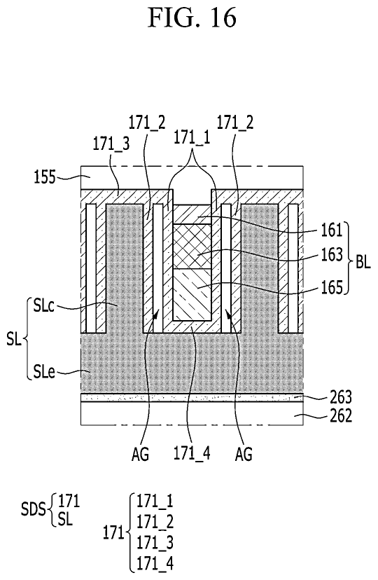

The air gap AG may be placed within the shielding insulation layer 171. For example, referring to FIG. 16, the shielding insulation layer 171 includes a first portion 171_1 in contact with the bit line BL in the first direction D1, a second portion 171_2 in contact with the extending portion SLc of the shielding pattern SL in the first direction D1, a third portion 171_3 in contact with the extending portion SLc of the shielding pattern SL in the third direction D3, and a fourth portion 171_4 placed between the body portion SLe of the shielding pattern SL and the bit line BL. The air gap AG may be disposed between the first portion 171_1 and the second portion 171_2 of the shielding insulation layer 171. One end of the air gap AG in the third direction D3 may be in contact with the body portion SLe of the shielding pattern SL, and another end of the air gap AG in the third direction D3 may be in contact with the third portion 171_3 of the shielding insulation layer 171. The air gap AG may be surrounded by the first portion 171_1, the second portion 171_2, and the third portion 171_3 of the shielding insulation layer 171, and the body portion SLe of the shielding pattern SL.

In FIG. 16, the length of air gap AG in the third direction D3 may be equal to or longer than the length of the metal pattern 163 of the bit line BL in the third direction D3. Additionally, the height of the lower end of the air gap AG in the third direction D3 may be equal to or lower than the height of the lower end of the metal pattern 163 of the bit line BL in the third direction D3, and the height of the upper end of the air gap AG in the third direction D3 may be equal to or higher than the height of the upper end of the metal pattern 163 of the bit line BL in the third direction D3. For example, the air gap AG may extend in the third direction D3 and overlap with the metal pattern 163 of the bit line BL in the first direction D1. Accordingly, the semiconductor memory device may control the coupling between the bit lines BL through the air gap AG.

For example, the shielding pattern SL may include a conductive material, and the shielding insulation layer 171 may include an insulating material. Accordingly, the semiconductor memory device may solve or help improve upon a problem of the capacitance of the bit line BL increasing due to the shielding structure SDS by sufficiently isolating the bit line BL and the shielding structure SDS while controlling the coupling between the bit lines BL through the conductive shielding structure.

Th conductive material of the shielding pattern SL, for example, may include a conductive metal nitride, a conductive metal silicon nitride, a metal carbonitride, a conductive metal silicide, a conductive metal oxide, a 2D material such as graphene and/or boron nitride, a metal, or a combination thereof.

The insulating material of the shielding insulation layer 171, for example, may include a silicon oxide layer, a silicon oxynitride layer, a silicon nitride layer, or a combination thereof.

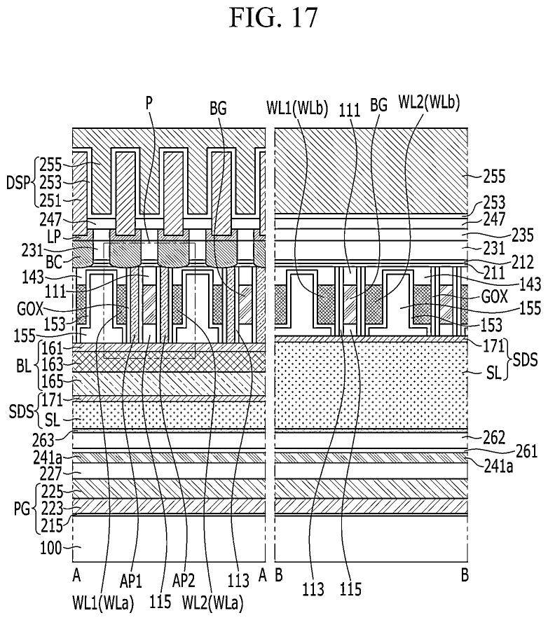

FIG. 17 to FIG. 19 are views to explain a semiconductor memory device according to various example embodiments and corresponding to FIG. 14 to FIG. 16, respectively.

In FIG. 17 to FIG. 19, the shielding pattern SL may include a low-dielectric material, and the shielding insulation layer 171 may have an air gap AG.

The low-dielectric material included in the shielding pattern SL may include, for example, a hydrocarbon compound, carbide, carbon, or a combination thereof, or the low-dielectric material included in the shielding pattern SL may include, for example, carbon doped silicon oxide (SiOC) and/or porous silicon oxide.

The shielding insulation layer 171 may include an insulating material, for example, the insulating material may include a silicon oxide layer, a silicon oxynitride layer, a silicon nitride layer, or a combination thereof.

Accordingly, the semiconductor memory device may improve the integration by reducing the gap between the word lines WL1 and WL2 by including the back gate electrode BG, and may prevent or reduce the coupling between the bit lines BL without a conductive shielding structure by sufficiently isolate the bit lines BL as the shielding pattern SL includes the low-dielectric material, and the shielding insulation layer 171 has the air gap AG.

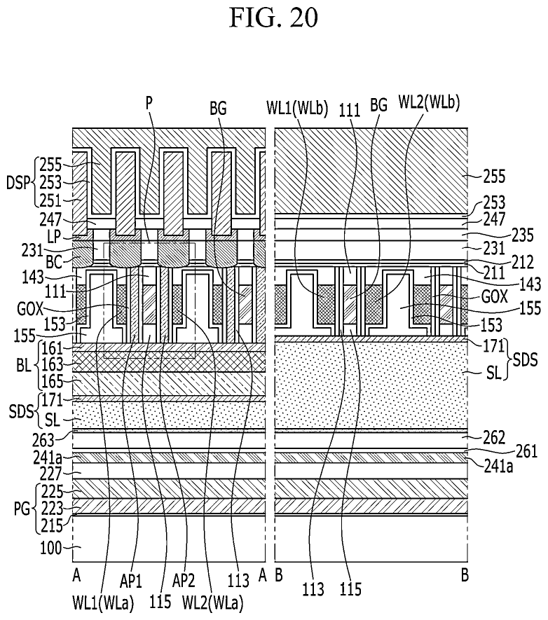

FIG. 20 to FIG. 22 are views to explain a semiconductor memory device according to various example embodiments and corresponding to FIG. 14 to FIG. 16, respectively.

In FIG. 20 to FIG. 22, the shielding pattern SL may include an insulating material, and the shielding insulation layer 171 may have an air gap AG.

The insulating material included in the shielding pattern SL may include, for example, a silicon oxide layer, a silicon oxynitride layer, a silicon nitride layer, or a combination thereof.

The shielding pattern SL may include a body portion SLe and an extending portion SLc. The body portion Sle of the shielding pattern SL may extend along the first direction D1 and the second direction D2, be placed between the shielding insulation layer 171 and the bonding insulation layer 263 in the third direction D3, and be in contact with the upper surface of the bonding insulation layer 263. The extending portion SLc of the shielding pattern SL may be placed on the body portion Sle of the shielding pattern SL in the third direction D3, be disposed between the bit lines BL adjacent in the first direction D1, and the extend along the second direction D2.

In FIG. 20 to FIG. 22, the shielding pattern SL is shown to include the body portion SIe and the extending portion SLc, but it is not limited thereto. The shielding pattern SL may include only the extending portion SLc). In this case, the shielding pattern SL may be placed between the bit lines BL adjacent in the first direction D1. The shielding pattern SL may extend along the second direction D2.

Additionally or alternatively, the shielding insulation layer 171 may also include an insulating material, and for example, the insulating material included in the shielding insulation layer 171 may include a silicon oxide layer, a silicon oxynitride layer, a silicon nitride layer, or a combination thereof. As an example, the insulating material included in the shielding pattern SL and the insulating material included in the shielding insulation layer 171 may be the same, and in this case, unlike shown in FIG. 20 to FIG. 22, the boundary between the shielding pattern SL and the shielding insulation layer 171 may not be distinguished.

Accordingly, the semiconductor memory device may improve the integration by reducing the gap between the word lines WL1 and WL2 by including the back gate electrode BG, and may prevent or reduce the coupling between the bit lines BL without a conductive shielding structure by sufficiently isolate the bit lines BL as the shielding insulation layer 171 has the air gap AG.

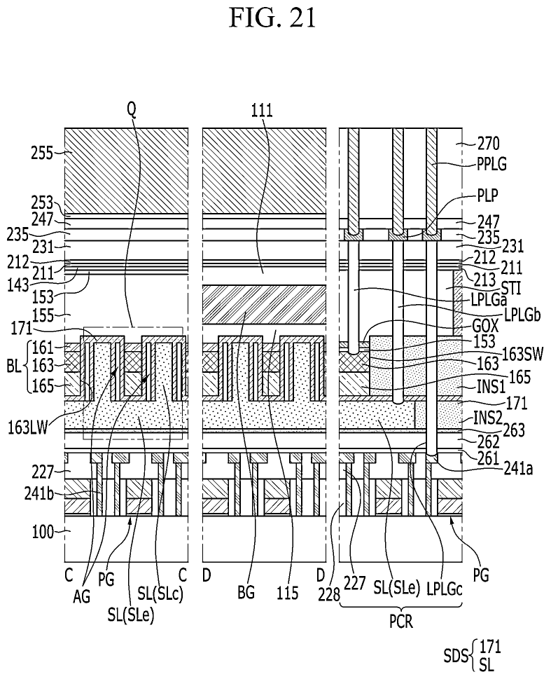

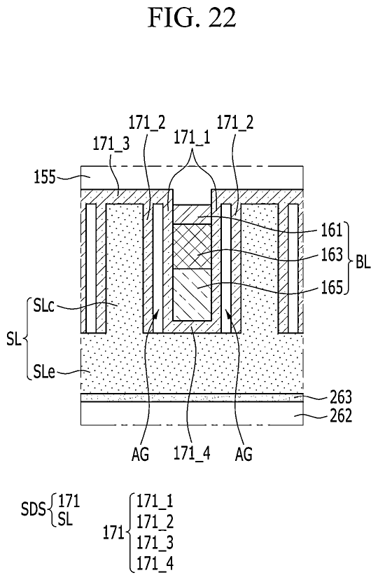

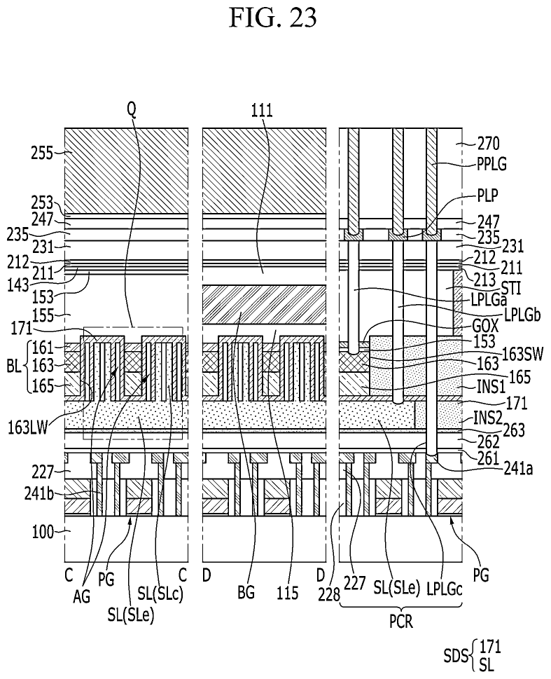

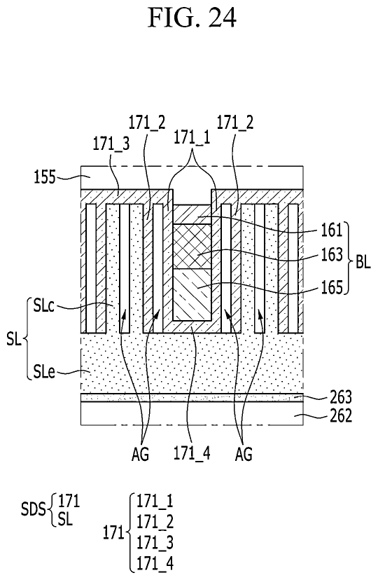

FIG. 23 and FIG. 24 are views to explain a semiconductor memory device according to various example embodiments and corresponding to FIG. 21 and FIG. 22, respectively.

In FIG. 23 and FIG. 24, as shown in FIG. 21 and FIG. 22, the shielding pattern SL may include an insulating material, and the shielding insulation layer 171 may have an air gap AG. However, in FIG. 23 and FIG. 24, the shielding pattern SL may also have an air gap AG.

The air gap AG of the shielding pattern SL may be filled with air or may be in a vacuum state. The air gap AG may be disposed on the body portion SLe of the shielding pattern SL in the third direction D3, be disposed within the extending portion SLc of the shielding pattern SL, and extend along the second direction D2.

In FIG. 24, the length of the air gap AG of the shielding pattern SL in the third direction D3 may be equal to or longer than the length of the metal pattern 163 of the bit line BL in the third direction D3. Additionally or alternatively, the height of the lower end of the air gap AG of the shielding pattern SL in the third direction D3 may be the same as or lower than the height of the lower end of the metal pattern 163 of the bit line BL in the third direction D3, and the height of the upper end of the air gap AG of the shielding pattern SL in the third direction D3 may be equal to or higher than the height of the upper end of the metal pattern 163 of the bit line BL in the third direction D3. For example, the air gap AG of the shielding pattern SL may extend in the third direction D3 and overlap with the metal pattern 163 of the bit line BL in the first direction D1. Accordingly, the semiconductor memory device may control the coupling between the bit lines BL through the air gap AG of the shielding pattern SL.

Accordingly, the semiconductor memory device may improve the integration by reducing the gap between the word lines WL1 and WL2 by including the back gate electrode BG, and may prevent or reduce the coupling between the bit lines BL without a conductive shielding structure by sufficiently isolate the bit lines BL as the shielding insulation layer 171 and the shielding pattern SL have the air gap AG.

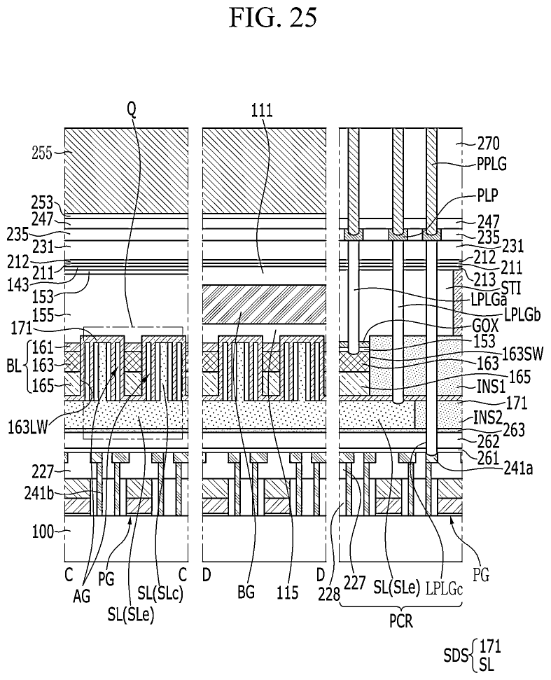

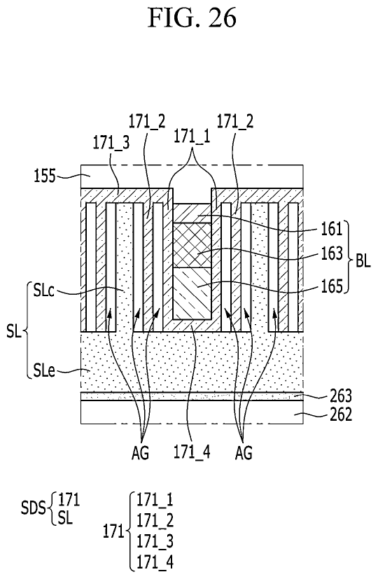

FIG. 25 and FIG. 26 are views to explain a semiconductor memory device according to various example embodiments and corresponding to FIG. 21 and FIG. 22, respectively.

In FIG. 25 and FIG. 26, as shown in FIG. 21 and FIG. 22, the shielding pattern SL may include an insulating material, and the shielding insulation layer 171 may have an air gap AG. However, in FIG. 25 and FIG. 26, the shielding structure SDS may have the air gap AG also between the shielding insulation layer 171 and the shielding pattern SL.

The air gap AG of the shielding structure SDS may be placed on the body portion SLe of the shielding pattern SL in the third direction D3 and be disposed between the shielding insulation layer 171 and the shielding pattern SL, and extend along the second direction D2.

Referring to FIG. 26, the shielding insulation layer 171 includes a first portion 171_1 in contact with the bit line BL in the first direction D1, a second portion 171_2 in contact with the extending portion SLc of the shielding pattern SL in the first direction D1, a third portion 171_3 in contact with the extending portion SLc of the shielding pattern SL in the third direction D3, and a fourth portion 171_4 placed between the body portion SLe of the shielding pattern SL and the bit line BL. The air gap AG of the shielding structure SDS may be disposed between the second portion 171_2 of the shielding insulation layer 171 and the extending portion SLc of the shielding pattern SL. One end of the air gap AG of the shielding structure SDS in the third direction D3 may be in contact with the body portion SLe of the shielding pattern SL, and another end of the air gap AG of the shielding structure SDS in the third direction D3 may be in contact with the third portion 171_3 of the shielding insulation layer 171. The air gap AG of the shielding structure SDS may be surrounded by the second portion 171_2 and the third portion 171_3 of the shielding insulation layer 171, and the body portion SLe and the extending portion SLc of the shielding pattern SL.

Accordingly, the semiconductor memory device may improve the integration by reducing the gap between the word lines WL1 and WL2 by including the back gate electrode BG, and may prevent or reduce the coupling between the bit lines BL without a conductive shielding structure by sufficiently isolate the bit lines BL as the shielding insulation layer 171 and the shielding pattern SL have the air gap AG.

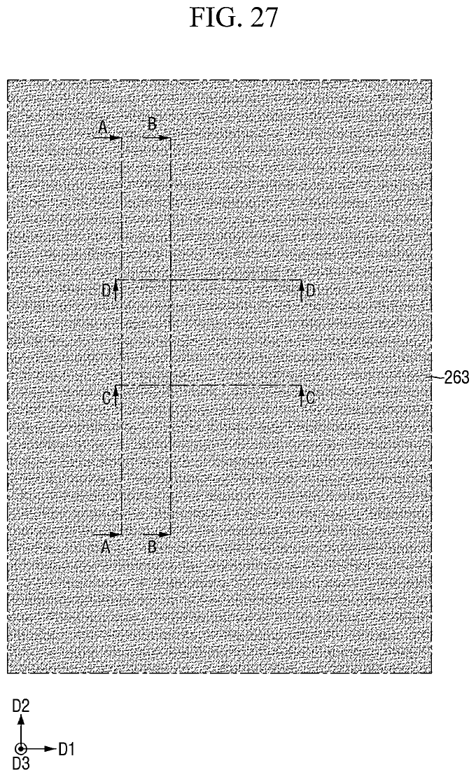

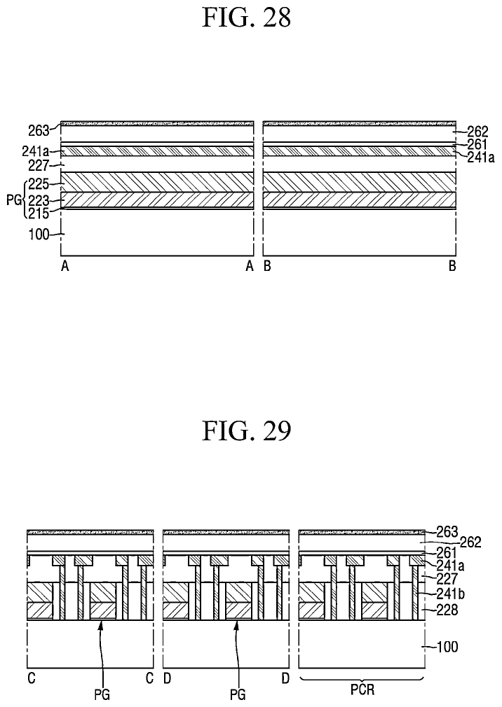

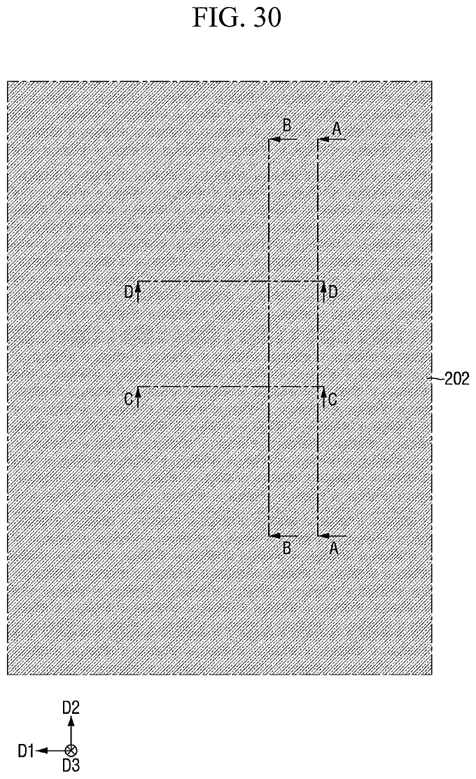

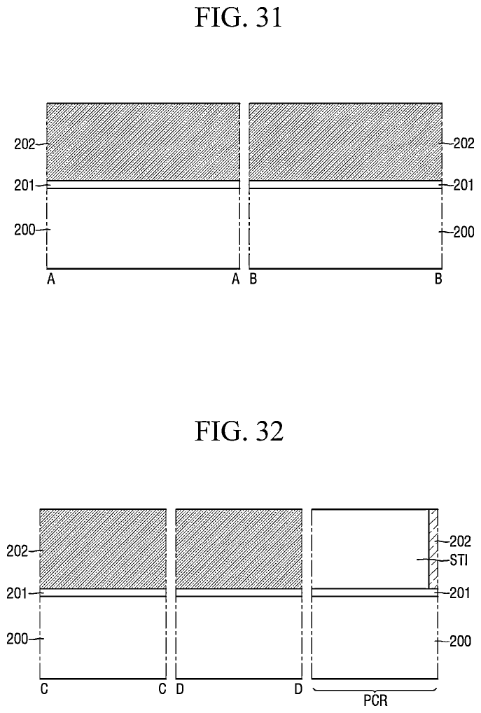

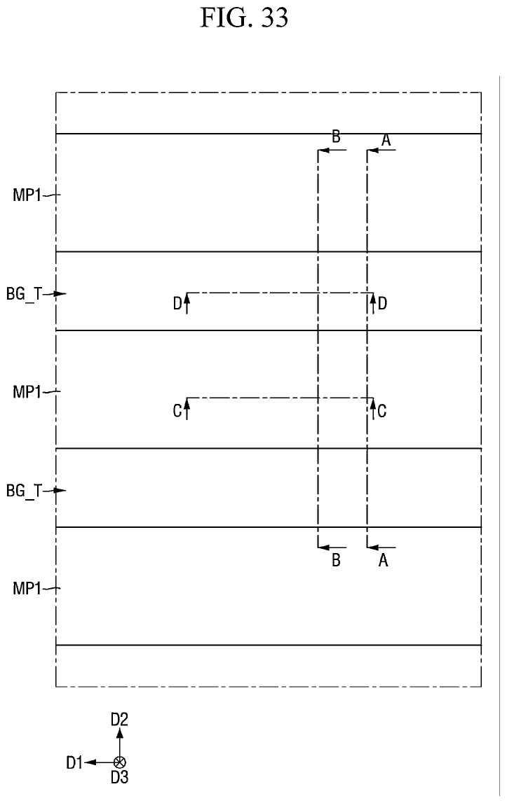

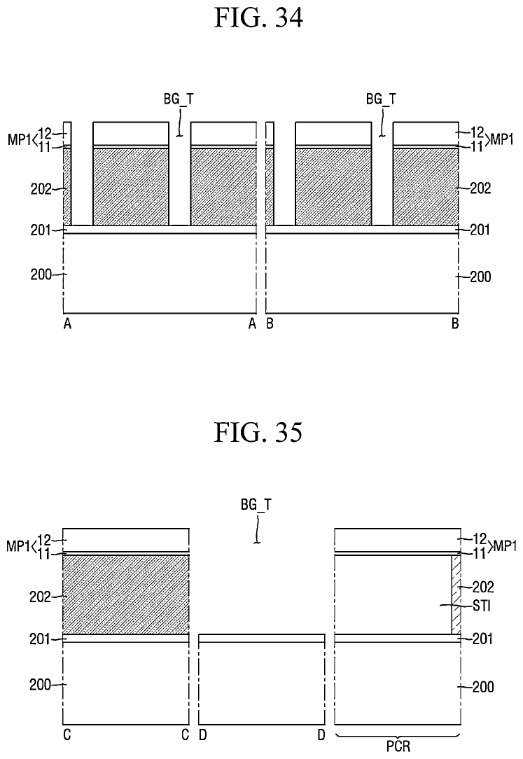

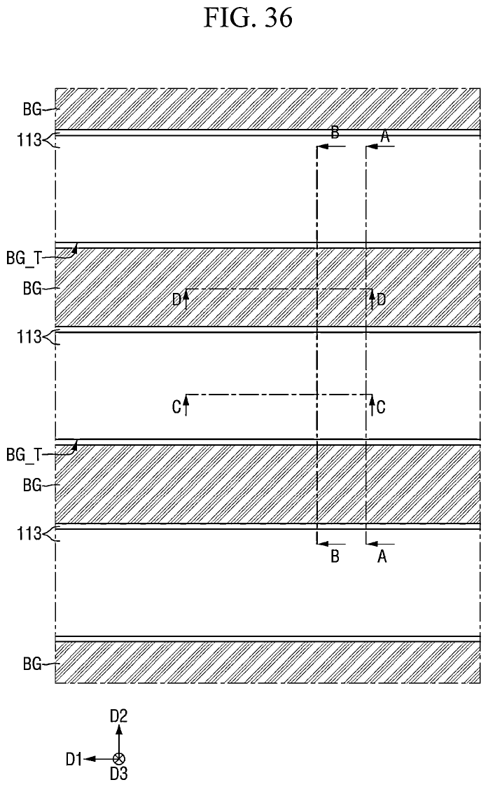

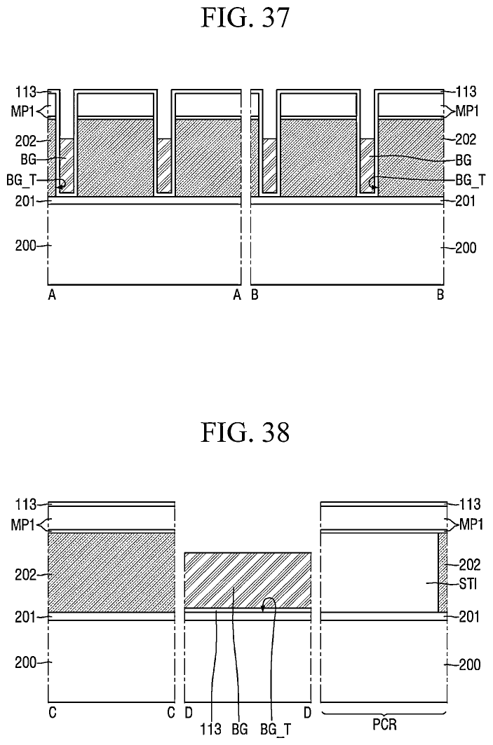

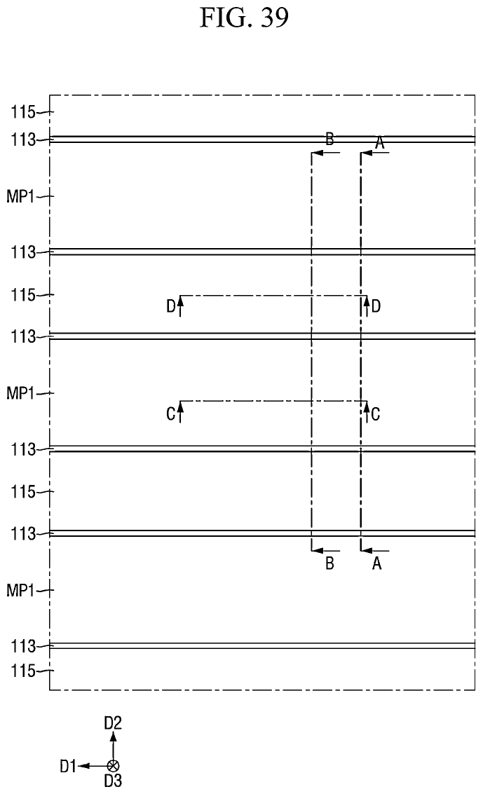

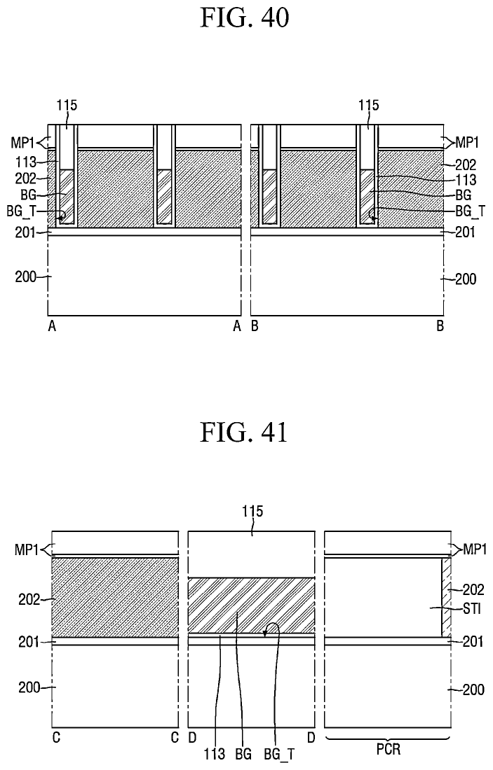

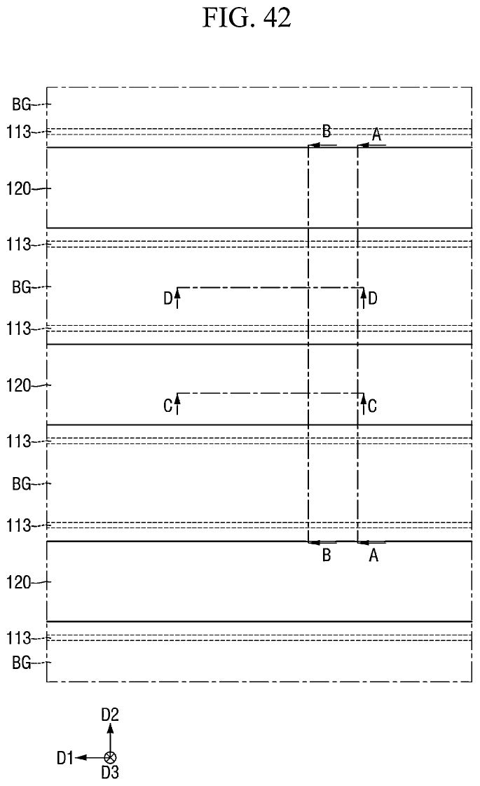

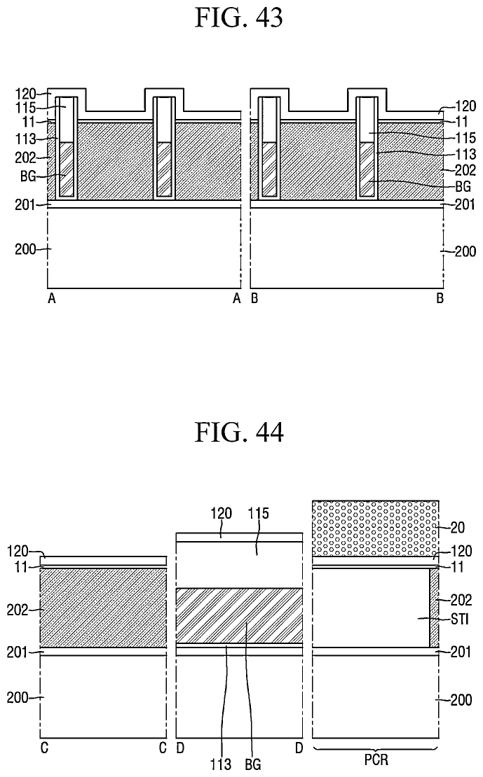

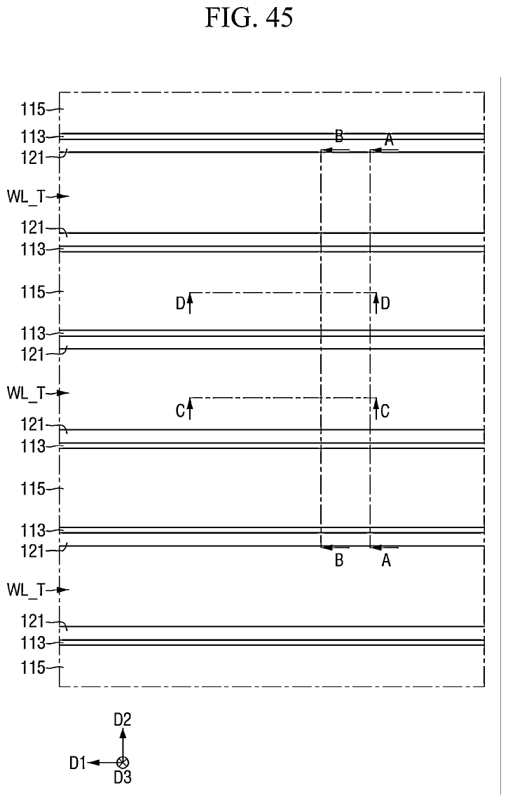

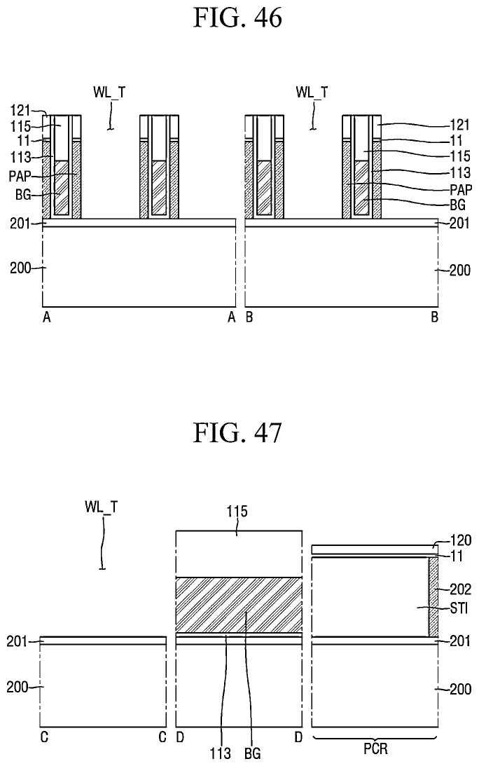

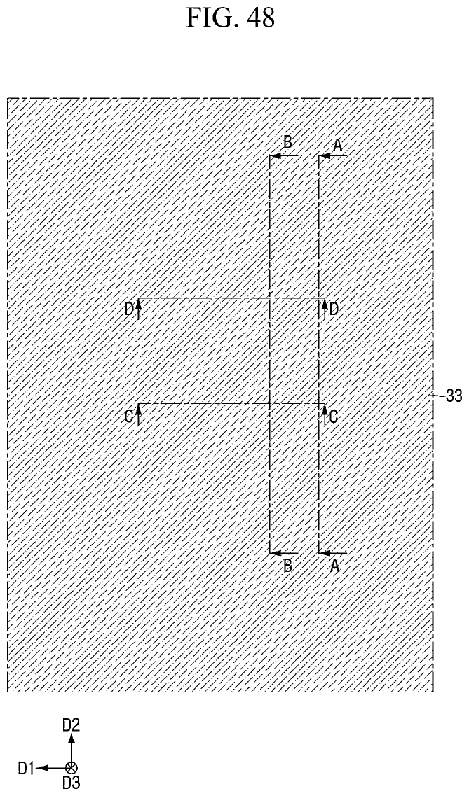

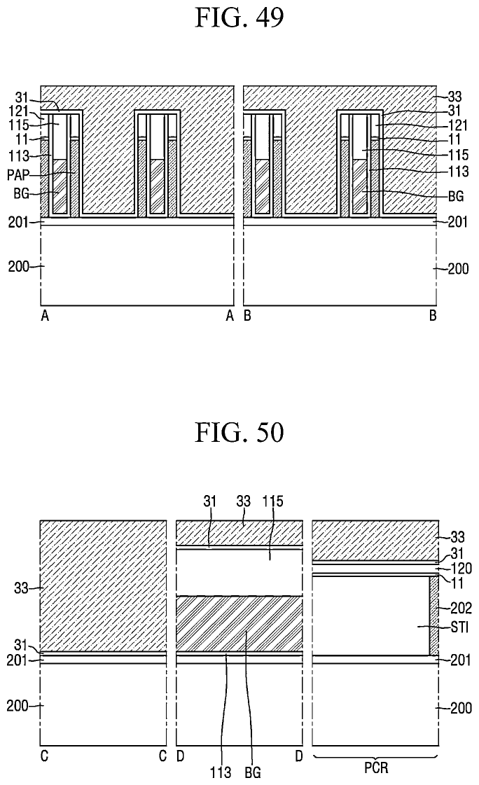

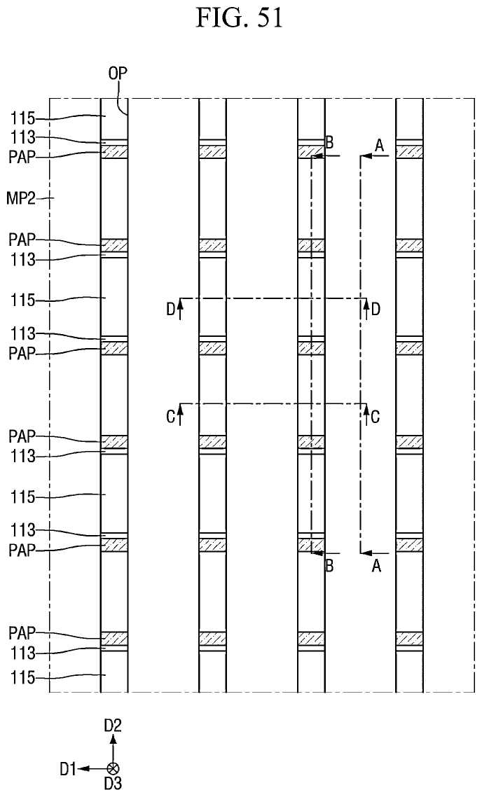

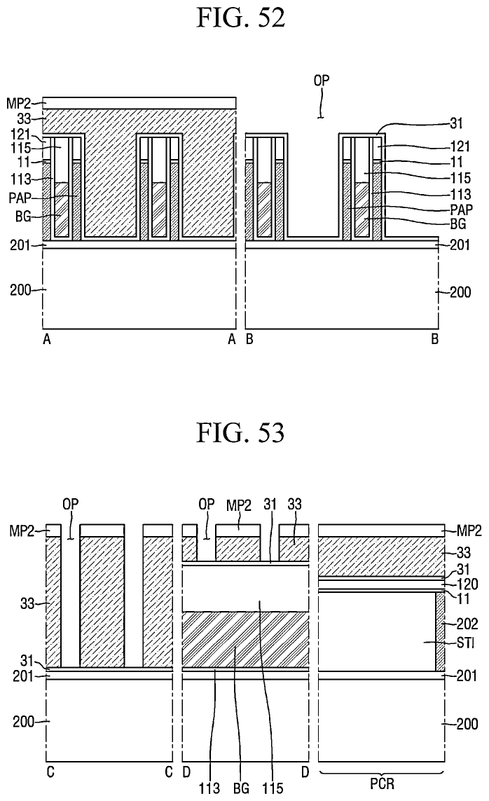

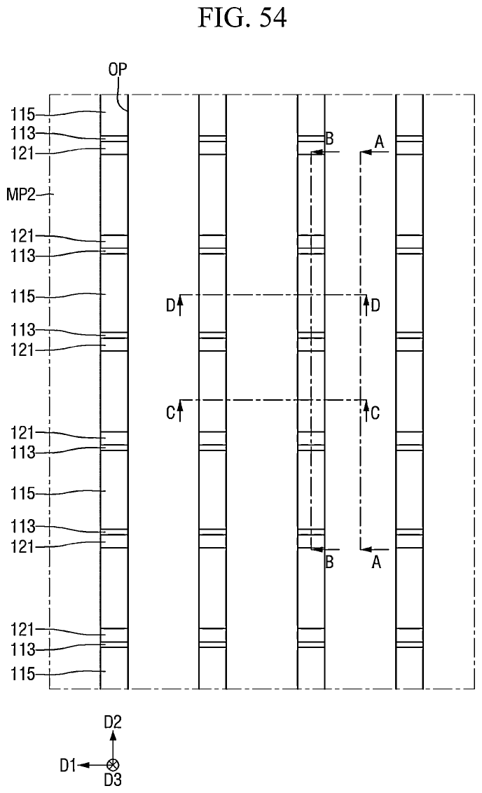

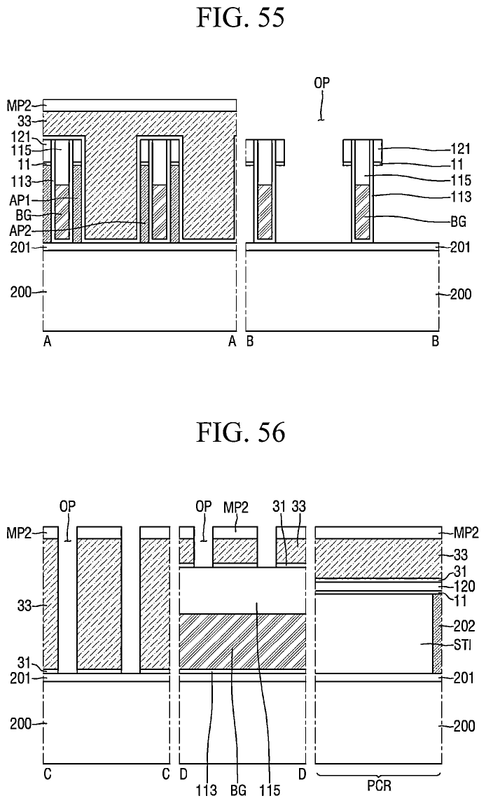

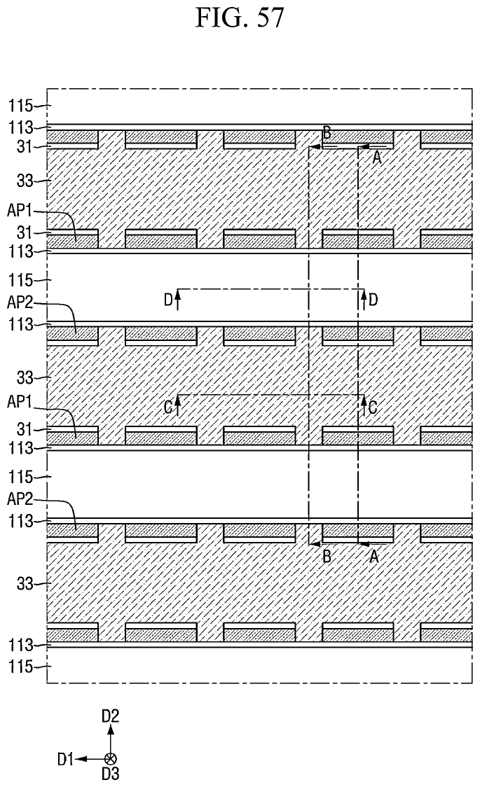

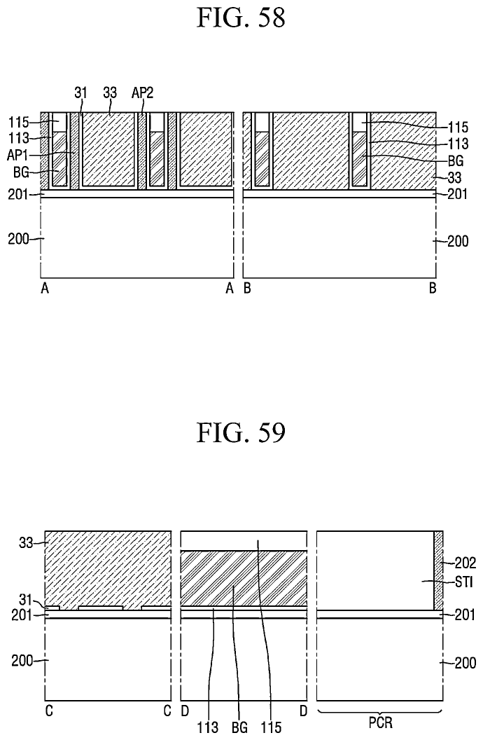

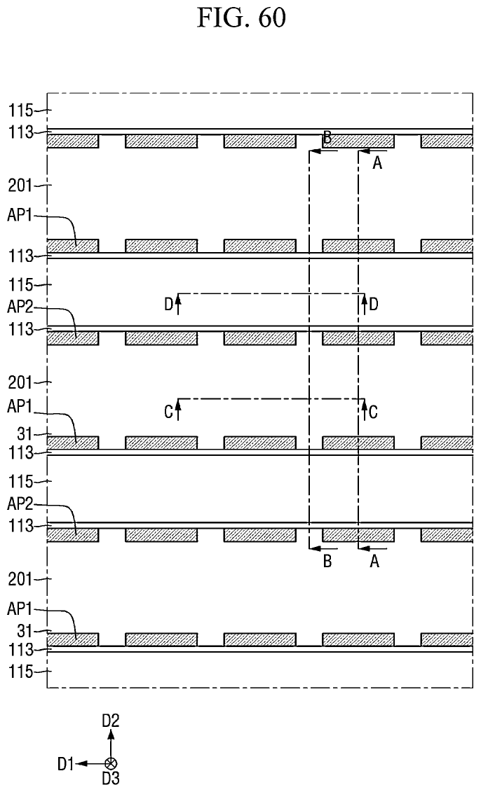

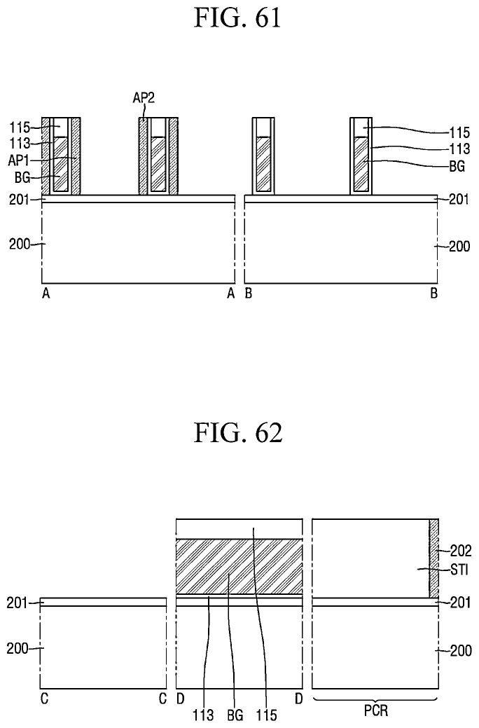

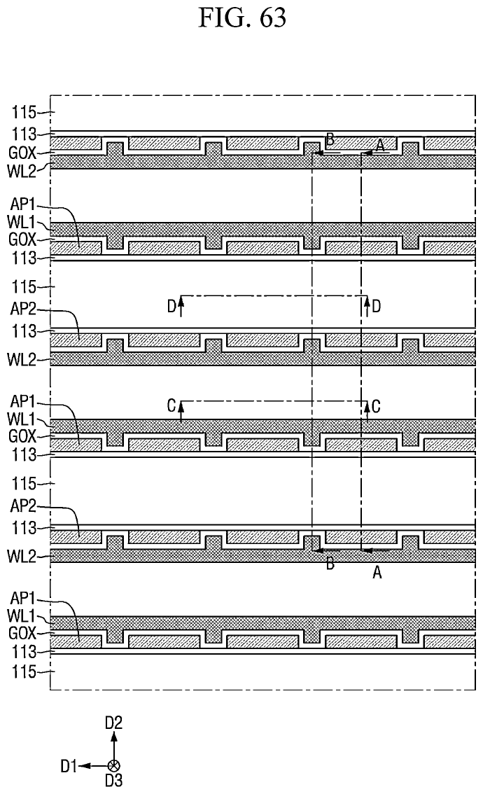

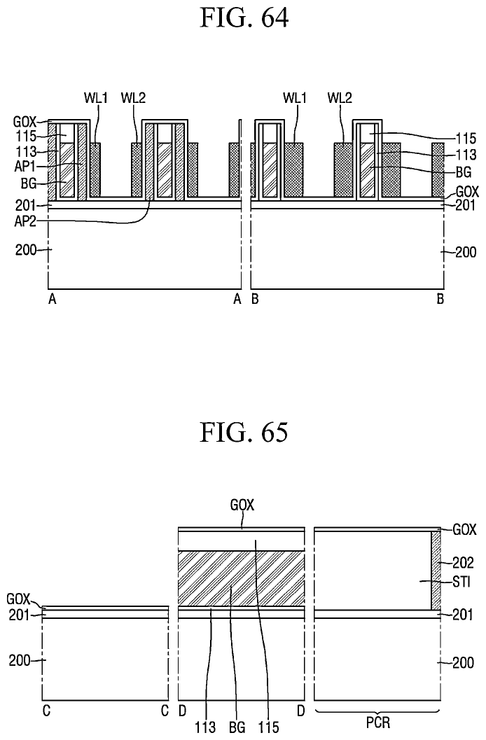

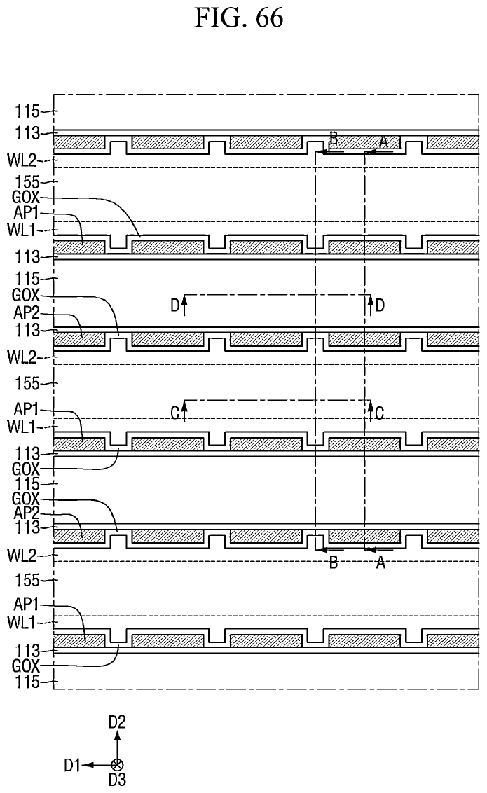

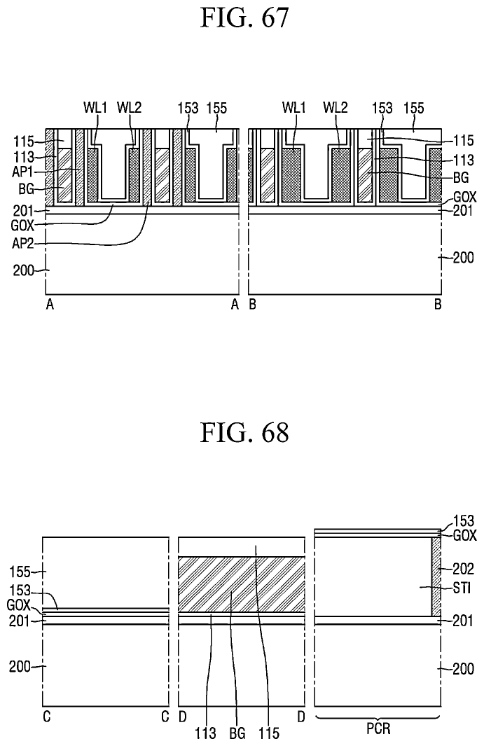

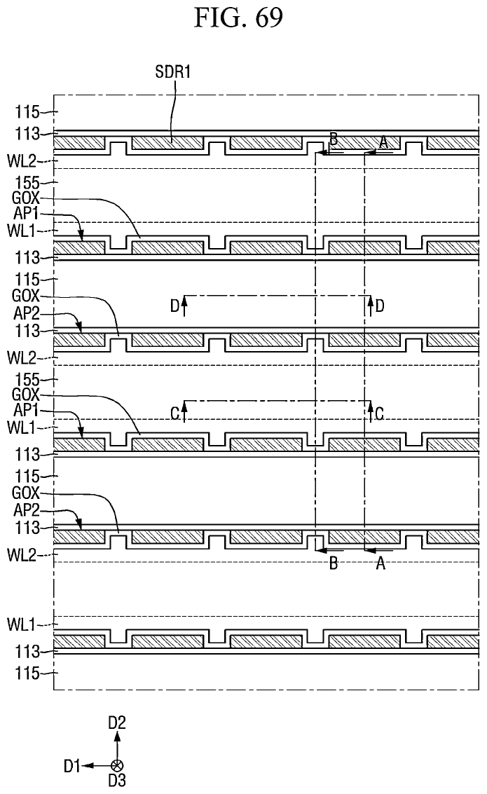

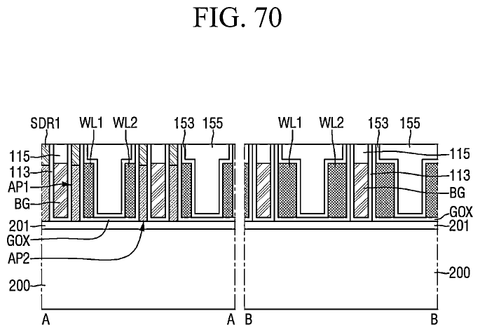

FIG. 27 to FIG. 113 are views to explain a method of manufacturing a semiconductor memory device according to some example embodiments.

For reference, a cutting line and a coordinate system shown in FIG. 30 to FIG. 85 are states that the cutting line and the coordinate system of FIG. 2 are inverted in the first direction D1.

Referring to FIG. 27 to FIG. 29, a peripheral gate structure PG may be formed on a substrate 100.

A peripheral wire line 241a and a peripheral contact plug 241b may be formed on the substrate 100, for example with a physical vapor deposition (PVD) process and/or a chemical vapor deposition (CVD) process. A first peripheral upper insulation layer 261 and a second peripheral upper insulation layer 262 may be sequentially formed on the peripheral wire line 241a and the peripheral contact plug 241b. A bonding insulation layer 263 may be formed on the second peripheral upper insulation layer 262.

Referring to FIG. 30 to FIG. 32, a sub-substrate structure including a sub-substrate 200, a buried insulation layer 201, and an active layer 202 may be provided.

The buried insulation layer 201 and the active layer 202 may be provided on a sub-substrate 200. The sub-substrate 200, the buried insulation layer 201, and the active layer 202 may be or may include a silicon-on-insulator substrate (an SOI substrate).

The sub-substrate 200 may include a cell array region CAR and a peripheral circuit region PCR. The sub-substrate 200 may be or may include, for example, a silicon substrate, a germanium substrate, and/or a silicon-germanium substrate, etc., and may or may not be doped.

The buried insulation layer 201 may be or may include a buried oxide (BOX) formed by a SIMOX (separation by implanted oxygen) method or a bonding and layer transfer method. Alternatively or additionally, the buried insulation layer 201 may be or may include an insulation layer formed by a chemical vapor deposition (CVD) method. The buried insulation layer 201 may include, for example, a silicon oxide layer, a silicon nitride layer, a silicon oxynitride layer, and/or a low dielectric constant insulation layer.

The active layer 202 may be a monocrystalline semiconductor layer. The active layer 202 may be, for example, a monocrystalline silicon substrate, a germanium substrate, and/or a silicon-germanium substrate, etc. The active layer 202 may have a first surface and a second surface & third direction D3, and the second surface of the active layer 202 may be in contact with the buried insulation layer 201.

An isolation layer STI may be formed within the active layer 202 of the peripheral circuit region PCR. The isolation layer STI may be formed by patterning the active layer 202 of the peripheral circuit region PCR to form a device separation trench that exposes the buried insulation layer 201, and then burying an insulating material within the device separation trench. In some example embodiments, the isolation structure STI may be formed with a shallow trench isolation (STI) process. The upper surface of the isolation layer STI may be substantially coplanar with the first surface of the active layer 202.

Referring to FIG. 33 to FIG. 35, a first mask pattern MP1 may be formed on the active layer 202.

The first mask pattern MP1 may have line-shaped openings extending along the first direction D1 in the cell array region CAR. The first mask pattern MP1 may include a first lower mask layer 11 and a first upper mask layer 12 sequentially stacked. The first upper mask layer 12 may be made of a material that has an etching selectivity for the first lower mask layer 11. For example, the first lower mask layer 11 may include silicon oxide, and the first upper mask layer 12 may include silicon nitride, but are not limited thereto.

Next, using the first mask pattern MP1 as an etching mask, the active layer 202 of the cell array region CAR may be anisotropic etched. Accordingly, back gate trenches BG_T extending in the first direction D1 may be formed in the active layer 202 of the cell array region CAR. The back gate trenches BG_T may expose the buried insulation layer 201 and be spaced apart with a certain interval in the second direction D2.

Referring to FIG. 36 to FIG. 38, a back gate insulating pattern 113 and back gate electrodes BG may be formed within the back gate trench BG_T.

More specifically, the back gate insulating pattern 113 may be formed along the sidewall and the bottom surface of the back gate trench BG_T and the upper surface of the first mask pattern MP1. A back gate electrode layer may be formed on the back gate insulating pattern 113. The back gate electrode layer may fill the back trench gate BG_T. Then, by isotropically etching the back gate electrode layer (e.g., with a wet etching process), back gate electrodes BG extending in the first direction D1 may be formed. The back gate electrodes BG may fill a part of the back gate trench BG_T.

Meanwhile, according to some example embodiments, before forming the back gate insulating pattern 113, a vapor doping (GPD) process and/or a plasma doping (PLAD) process and/or a beamline implantation process may be performed. Through the above-described process, impurities may be doped in or incorporated into the active layer 202 exposed by the back gate trench BG_T.

Referring to FIG. 39 to FIG. 41, back gate capping patterns 115 may be formed on the back gate electrode BG.

The back gate capping pattern 115 may fill the remainder of the back gate trench BG_T. If the back gate capping pattern 115 and the back gate insulating pattern 113 are formed of the same material (e.g., silicon oxide), while the back gate capping pattern 115 is formed, the back gate insulating pattern 113 on the upper surface of first mask pattern MP1 may be removed.

Meanwhile, before forming the back gate capping patterns 115, a vapor doping (GPD) process and/or a plasma doping (PLAD) process and/or a beamline implantation process may be performed. Through this, impurities may be doped in or incorporated into the active layer 202 through the back gate trench BG_T where the back gate electrode BG is formed.

After forming the back gate capping patterns 115, the first upper mask layer 12 may be removed. The back gate capping patterns 115 may have a shape that protrudes above the upper surface of the first lower mask layer 11.

Referring to FIG. 42 to FIG. 44, a spacer layer 120 may be formed along the upper surface of the first lower mask layer 11, the sidewall of the back gate insulating patterns 113, and the upper surface of the back gate capping patterns 115. The spacer layer 120 may be formed with a uniform thickness. Depending on the deposit thickness of the spacer layer 120, the width of the activation patterns of the vertical channel transistors may be determined. The spacer layer 120 may be formed of an insulating material. The spacer layer 120, for example, may include silicon oxide, silicon oxynitride, silicon nitride, silicon carbide (SiC), a silicon carbon nitride layer (SiCN), and a combination thereof.

Subsequently, a peripheral mask pattern 20 may be formed on the spacer layer 120 of the peripheral circuit region PCR. The peripheral mask pattern 20 may expose the cell array region CAR.

Referring to FIG. 45 to FIG. 47, by performing an anisotropic etching process on the spacer layer 120, a pair of spacer pattern 121 may be formed on the sidewall of the back gate insulating pattern 113.

Using the spacer pattern 121 as an etching mask, an anisotropic etching process for the active layer 202 may be performed. Through this, a pair of pre-activation patterns PAP separated from each other may be formed on both sides of each back gate insulating pattern 113. As the pre-activation patterns PAP are formed, the buried insulation layer 201 may be exposed.

The pre-activation patterns PAP may have a line shape extending parallel to the back gate electrode BG in the first direction D1. A word line trench WL_T may be formed between the pre-activation patterns PAP adjacent to each other in the second direction D2.

After forming the spacer pattern 121, the peripheral mask pattern 20 may be removed. A portion of the spacer layer 120 may remain on first lower mask layer 11 of the peripheral circuit region PCR.

Referring to FIG. 48 to FIG. 50, an etch stopping layer 31 may be formed along the sidewall and the bottom of the word line trench WL_T.

A sacrificial layer 33 that fills the word line trench WL_T in which the etch stopping layer 31 is formed may be formed. The sacrificial layer 33 may fill the word line trench WL_T. The sacrificial layer 33 may have a substantially flat upper surface. The etch stopping layer 31 may be formed by depositing an insulating material, for example, silicon oxide, but it is not limited thereto. The sacrificial layer 33 may be formed of an insulating material with an etching selectivity for the etch stopping layer 31. As an example, the sacrificial layer 33 may be one of insulating materials and silicon oxide layers formed using a spin on glass (SOG) technology, but it is not limited thereto.

The etch stopping layer 31 and the sacrificial layer 33 may be sequentially stacked on the spacer layer 120 of the peripheral circuit region PCR.

Referring to FIG. 51 to FIG. 53, a second mask pattern MP2 may be formed on the sacrificial layer 33.

The second mask pattern MP2 may be formed of a material with an etching selectivity for the sacrificial layer 33. The second mask pattern MP2 may have a line form that extends to the second direction D2. As another example, the second mask pattern MP2 may have the form of a line extending in the diagonal direction for the first direction D1 and the second direction D2.

Subsequently, using the second mask pattern MP2 as an etching mask, the sacrificial layer 33 may be etched to form openings OP. The openings OP may expose the etch stopping layer 31.

Referring to FIG. 54 to FIG. 56, the etch stopping layer 31 exposed by openings OP may be removed.

The openings OP may expose the upper surface of the buried insulation layer 201. Additionally, the openings OP may expose a portion of the pre-activation patterns PAP.

Next, by etching the pre-activation patterns PAP exposed on the openings OP, a first activation pattern AP1 and a second activation pattern AP2 may be formed on both sides of the back gate electrode BG. On the first sidewall of the back gate electrode BG, the first activation patterns AP1 may be formed spaced apart from each other in the first direction D1. On the second sidewall of the back gate electrode BG, the second activation patterns AP2 may be formed spaced apart from each other in the first direction D1. In another example, when the second mask pattern MP2 extends in the diagonal direction, the first and second activation patterns AP1 and AP2 may be arranged to face each other in the diagonal direction. As the first activation pattern AP1 and the second activation pattern AP2 are formed, the openings OP may expose a part of the back gate insulating pattern 113.

Referring to FIG. 57 to FIG. 59, a sacrificial layer 33 may be filled within the openings OP. The sacrificial layer 33 that fills the opening OP may be the same material as the sacrificial layer 33 that fills the word line trench (WL_T in FIG. 51 and FIG. 52).

After filling the sacrificial layer 33 within the opening OP, the second mask pattern MP2 may be removed. A planarization process may be performed on the sacrificial layer 33 and the etch stopping layer 31 so that the upper surface of the back gate capping pattern 115 is exposed. Next, the spacer pattern 121 and the first lower mask layer 11 may be removed. Through this, the first activation pattern AP1 and the second activation pattern AP2 may be exposed. The spacer pattern 121 and the first lower mask layer 11 may be removed using a planarization process, but it is not limited to this.

Referring to FIG. 60 to FIG. 62, the sacrificial layer 33 and the etch stopping layer 31 on the buried insulation layer 201 may be removed.

Accordingly, the buried insulation layer 201 may be exposed.

Referring to FIG. 63 to FIG. 65, a gate insulating pattern GOX may be formed along the sidewall of the first activation pattern AP1, the sidewall of the second activation pattern AP2, the upper surface of the back gate capping pattern 115, and the upper surface of the buried insulation layer 201.

The gate insulating pattern GOX may be deposited on the active layer 202 and the isolation layer STI in the peripheral circuit region PCR. The gate insulating pattern GOX may be formed using at least one of a physical vapor deposition (PVD), a thermal chemical vapor deposition (a thermal CVD), a low pressure chemical vapor deposition (LP-CVD), a plasma enhanced chemical vapor deposition (PE-CVD), or an atomic layer deposition (ALD) technologies, but it is not limited thereto.

Next, a first word line WL1 and a second word line WL2 may be formed on the gate insulating pattern GOX. The first and second word lines WL1 and WL2 may be formed on the sidewalls of the first and second activation patterns AP1 and AP2.

Forming the first and second word lines WL1 and WL2 may include depositing a gate electrode layer on the gate insulating pattern GOX and then performing an anisotropic etching process such as a dry etching process on the gate electrode layer. Here, the deposit thickness of the gate electrode layer may be less than half the width of the word line trench (WL_T in FIG. 51 and FIG. 52).

During the anisotropic etching process for the gate electrode layer, the gate insulating pattern GOX may be used as an etch stopping layer. Unlike shown, the gate insulating layer 151 may be over-etched so the buried insulation layer 201 may be exposed. Depending on the anisotropic etching process for the gate electrode layer, the first and second word lines WL1 and WL2 may have various shapes.

The upper surface of the first word line WL1 and the upper surface of the second word line WL2 may be placed at a lower level than the upper surface of the first and second activation patterns AP1 and AP2.

As an example, after forming the first and second word lines WL1 and WL2, a vapor doping (GPD) process or a plasma doping (PLAD) process may be performed. Accordingly, impurities may be doped in or incorporated in the first and second activation patterns AP1 and AP2 through the gate insulating pattern GOX exposed by the first and second word lines WL1 and WL2.

Referring to FIG. 66 to FIG. 68, a gate separation liner 153 and a, gate separation filling layer 155 may be formed on the first and second word lines WL1 and WL2.

More specifically, the gate separation liner 153 may be formed on the sub-substrate 200. The gate separation liner 153, for example, may include silicon nitride (SiN), silicon oxynitride layer (SiON), silicon carbide (SiC), silicon carbonitride layer (SiCN), and a combination thereof. The gate separation liner 153 may cover the surfaces of the word lines WL1 and WL2.

Subsequently, a gate separation filling layer 155 may be formed to fill the word line trench (WL_T in FIG. 51 and FIG. 52) in which the gate separation liner 153 is formed. Here, the gate separation filling layer 155 may be formed of an insulating material different from the gate separation liner 153. Afterwards, a planarization process may be performed on the gate separation liner 153 and the gate separation filling layer 155 so that the upper surfaces of the back gate capping patterns 115 are exposed.

Meanwhile, before forming the gate separation filling layer 155, a mask pattern exposing the cell array region CAR may be formed on the gate separation liner 153 of the peripheral circuit region PCR. In this case, the gate separation filling layer 155 may not be formed in the peripheral circuit region PCR.

Referring to FIG. 69 and FIG. 70, a first dopant region SDR1 may be formed within the first and second activation patterns AP1 and AP2.

The impurity is doped in a part of the first activation pattern AP1 and a part of the second activation pattern AP2, thereby forming the first dopant region SDR1.

Forming the first dopant region SDR1 may be an optional process. The subsequent manufacturing method will be explained using the case where the first dopant region SDR1 is not formed.

Referring to FIG. 71 to FIG. 73, a polysilicon pattern 161 may be formed on the entire surface of the sub-substrate 200.

The polysilicon pattern 161 may be in contact with the first and second activation patterns AP1 and AP2 in the cell array region CAR. The polysilicon pattern 161 may be formed on the gate separation liner 153 in the peripheral circuit region PCR. The polysilicon pattern 161 may be undoped, or may be doped, e.g., in-situ and/or ex-situ doped.

Subsequently, a third mask pattern MP3, which exposes the peripheral circuit region PCR, may be formed on the polysilicon pattern 161. By using the third mask pattern MP3 as an etching mask, the polysilicon pattern 161 on the peripheral circuit region PCR may be removed. In the peripheral circuit region PCR, the gate separation liner 153 may be exposed.

Referring to FIG. 74 to FIG. 76, a metal pattern 163 and a bit line mask pattern 165 may be formed on the polysilicon pattern 161 of the cell array region CAR.

The metal pattern 163 and the bit line mask pattern 165 may be formed on the gate separation liner 153 of the peripheral circuit region PCR.

Referring to FIG. 77 to FIG. 79, the bit line mask pattern 165, the metal pattern 163, and the polysilicon pattern 161 may be patterned to form bit lines BL extending in the second direction D2.

While forming the bit lines BL, a portion of the back gate capping pattern 115 may be etched. Additionally, while forming the bit lines BL, the bit line mask pattern 165, the metal pattern 163, the gate separation liner 153, and the gate insulating pattern GOX of the peripheral circuit region PCR may be etched. Accordingly, a part of the isolation layer STI and the active layer 202 may be exposed.

Referring to FIG. 80 to FIG. 82, a shielding insulation layer 171 may define a shielding region between the bit lines BL.

The shielding insulation layer 171 may have a substantially uniform thickness. The shielding insulation layer 171 may be formed on the entire surface of the sub-substrate 200. The deposit thickness of the shielding insulation layer 171 may be less than half the distance that the bit lines BL are spaced. As the shielding insulation layer 171 is formed, a shielding region may be defined between the bit lines BL by the shielding insulation layer 171. The shielding region may extend parallel to bit lines BL in the second direction D2.

The shielding insulation layer 171 may extend from the cell array region CAR to the peripheral circuit region PCR. That is, the end of the shielding insulation layer 171 may be placed on the peripheral circuit region PCR. On the other hand, before forming the shielding insulation layer 171, the first peripheral insulation layer INS1 may be filled to the side of the bit line BL disposed on the peripheral circuit region PCR in the first direction D1, and the shielding insulation layer 171 may cover the bit line BL and the first peripheral insulation layer INS1.

As an example, the shielding structure SDS may include a low-dielectric material. Here, the dielectric constant of the low-dielectric material may be lower than the dielectric constant of silicon oxide (SiO₂).

For example, the low-dielectric materials may include hydrocarbon compounds, carbide, carbon, or combinations thereof. In other words, the low dielectric material may be charcoal or ash including various types of hydrocarbon compounds, carbide, carbon, or combinations thereof produced while carbon cyclic of hydrocarbon-based polymer is broken by a thermal decomposition by heat decomposing hydrocarbon-based polymer. For example, the hydrocarbon-based polymer may include aromatic hydrocarbon polymer, (meth)acryl-based polymer, vinyl pyridine polymer, vinyl ester polymer, vinylpyrrolidone polymer, olefin polymer, or a combination thereof.

The thermal decomposition of hydrocarbon-based polymers to form low-dielectric materials may be achieved in a state that an oxygen supply is blocked, and a heat treatment temperature may be above a thermal decomposition temperature of hydrocarbon-based polymers. For example, after forming a material layer for the shielding structure SDS by using a hydrocarbon-based polymer, heat treatment may be performed at a temperature of 250° C. to 1000° C. in a state that an oxygen supply is blocked to produce the shielding structure SDS including a low-dielectric material.

For example, the low-dielectric material may include carbon doping silicon oxide (SiOC), and/or porous silicon oxide.

In the carbon doping silicon oxide, at least a part of the oxygen atom bonded to silicon in silicon oxide is substituted for an organic material group including carbon. For example, the carbon doping silicon oxide may be trimethylsilane (TMS) (BLACKDIAMONDTM), tetramethylcyclotetrasilane (TMCTS) (CoralTM), dimethyldimethoxysilane (DMDMOS) (AuroraTM), or hydrogen silsesoxoxane (HSG). Carbon doped silicon oxide may be referred to as an organo-silicate glass (OSG) and may be formed by a chemical vapor deposition (CVD) method using organo-silane (organo-silane) and organo-siloxane (organo-siloxane).

Porous silicon oxide may be formed by oxidizing carbon-doped silicon oxide and removing an organic material including carbon. For example, adding an oxidizing agent to carbon doped silicon oxide may oxidize the carbon doped silicon oxide to form silicon oxide (SiOₓ) and remove an organic material including carbon.

The oxidizing agent may include, for example, may include phosphoric acid (H₃PO₄), nitric acid (HNO₃), sulfuric acid (H₂SO₄), perchloric acid (HClO₄), chlorous acid (HClO₂), hydrogen peroxide (H₂O₂), sodium hypochlorite (NaOCl), deoxidation chlorine (ClO₂), peracetic acid (CH₃COOOH, PAA), ozone (O₃), or a combination thereof, or may include peracetic acid. Peracetic acid may be easily produced by mixing acetic acid and hydrogen peroxide and has the advantage of being relatively inexpensive.

Additionally, silicon oxide may be removed (striped) by adding an oxide etchant to carbon doped silicon oxide. The oxide etchant may remove silicon oxide by fluorinate silicon oxide with SiFw, or HySiFz (w, y, z are all positive integers that may or may not be equal to one another).

The oxide etchant may include, for example, a fluoride-based reducing agent. The fluoride-based reducing agent may include hydrofluoric acid (HF), hydrofluoroboric acid (HBF₄), ammonium fluoride (NH₄F), or a combination thereof, or hydrofluoric acid. Hydrofluoric acid is easy to obtain because it is widely used in the semiconductor manufacturing process.

For example, after forming the material layer for the shielding structure SDS including the carbon doped silicon oxide by using a chemical vapor deposition (CVD) method using organo-silane and organo-siloxane, porous silicon oxide may be formed by contacting the material layer for the shielding structure SDS with an oxidizing agent or an oxide etchant. For example, contacting the material layer for the shielding structure SDS with the oxidizing agent or the oxide etchant includes dipping the wafer on which the material layer for the shielding structure SDS is formed into the oxidizing agent or the oxide etchant for an appropriate time. As a temperature rises, an etch rate generally increases. For example, the oxidizing agent or the oxide etchant may have a temperature range of 25° C. to 80° C.

In addition, when using the oxidizing agent and the oxide etchant together, 30 volume % to 90 volume % of the oxidizing agent and 0.1 volume % to about 30 volume % of the oxide etchant may be included, or 30 volume % to 90 volume % of the oxide etchant, 0.1 volume % to 30 volume % of the oxide etchant, and 0.1 volume % to about 40 volume % of a pure water (a deionized water) may be included.

Referring to FIG. 83 to FIG. 85, the shielding structure SDS may be formed by forming the shielding pattern SL within the shielding region of the shielding insulation layer 171.

The shielding pattern SL may be formed between the bit lines BL. For example, forming the shielding pattern SL may form a shielding conductive layer to fill the shielding region on the shielding insulation layer 171. Accordingly, the shielding pattern SL may include an extending portion SLc placed within the shielding region of the shielding insulation layer 171 and extending in the second direction D2 and a body portion SLe covering the upper surface of the shielding insulation layer 171. Selectively, when recessing the upper surface of the shielding conductive layer, the shielding pattern SL may include only the extending portion SLc.

According to various example embodiments, while forming the shielding pattern SL, the body portion SLe of the shielding pattern SL may be extended to the peripheral circuit region PCR. Additionally, the second peripheral insulation layer INS2 may be filled on the side of the body portion SLe) of the shielding pattern SL in the first direction D1 disposed on the peripheral circuit region PCR.

Referring to FIG. 86 to FIG. 88, the sub-substrate 200 on which the back gate electrodes BG, the word lines WL1 and WL2, the activation patterns AP1 and AP2, the bit lines BL, and the shielding structure SDS are formed may be bonded to a substrate 100 in which a peripheral gate structure PG is formed.

By using a bonding adhesive film 263, the substrate 100 and the sub-substrate 200 may be bonded.

In this way, for example, as the first and second activation patterns AP1 and AP2 are formed of monocrystalline semiconductor material, the bit lines BL and the shielding structure SDS of the complex structure may be formed on the first and second activation patterns AP1 and AP2. Also, as the bit lines BL and the shielding structure SDS are formed and then jointed to the peripheral gate structure PG through a wafer bonding, the shielding structure SDS of the complex structure may be implemented on the peripheral gate structure PG.

Referring to FIG. 89 and FIG. 91, after bonding the substrate 100 and the sub-substrate 200, a rear lapping process of removing the sub-substrate 200 may be performed.

Removing the sub-substrate 200 may include exposing the buried insulation layer 201 by sequentially performing a grinding process and a dry etching process.

Referring to FIG. 92 to FIG. 94, the buried insulation layer 201 may be removed to expose the first activation pattern AP1 and the second activation pattern AP2.

The buried insulation layer 201 is removed, so that a part of the gate insulating pattern GOX and a part of the back gate insulating pattern 113 may be exposed.

Next, the exposed gate insulating pattern GOX and the exposed back gate insulating pattern 113 may be removed. Accordingly, the back gate electrode BG, the first word line WL1, and the second word line WL2 may be exposed.

Subsequently, by performing an etch-back process and/or a chemical mechanical planarization (CMP) process, a part of the back gate electrode BG, a part of the first word line WL1, and a part of the second word line WL2 may be removed.

Next, a back gate separation pattern 111 may be formed on the recessed back gate electrode BG. Also, on the recessed first and second word lines WL1 and WL2, a gate capping pattern 143 may be formed. The back gate separation pattern 111 and the gate capping pattern 143 may be formed simultaneously.

In the peripheral circuit region PCR, an inserted insulation layer 213 may be formed on the isolation layer STI and the active layer 202. As an example, the inserted insulation layer 213 may be the remaining portion remaining after removing the buried insulation layer 201. As another example, after forming the back gate separation pattern 111 and the gate capping pattern 143, the inserted insulation layer 213 that exposes the cell array region CAR may be formed.

Referring to FIG. 95 to FIG. 97, a lower contact etch stopping layer 211, an upper contact etch stopping layer 212, and a contact interlayer insulating layer 231 may be sequentially formed on the entire surface of the substrate 100.

Next, a contact hole exposing the first activation pattern AP1 and the second activation pattern AP2 may be formed within the lower contact etch stopping layer 211, the upper contact etch stopping layer 212, and the contact interlayer insulating layer 231. The contact pattern BC may be formed within the contact hole. The contact patterns BC may be formed on the first activation pattern AP1 and the second activation pattern AP2. The contact patterns BC may be connected to the first activation pattern AP1 and the second activation pattern AP2.

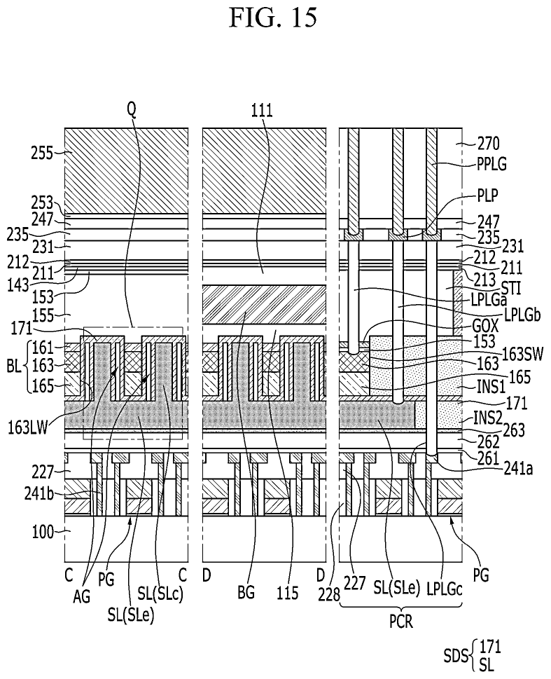

Unlike what is shown, a contact layer in contact with the first activation pattern AP1 and the second activation pattern AP2 may be formed on the entire surface of the substrate 100. Subsequently, the contact pattern BC may be formed by patterning the contact layer. Between the spaced contact patterns BC, a contact separation pattern (232 in FIG. 15) may be formed.

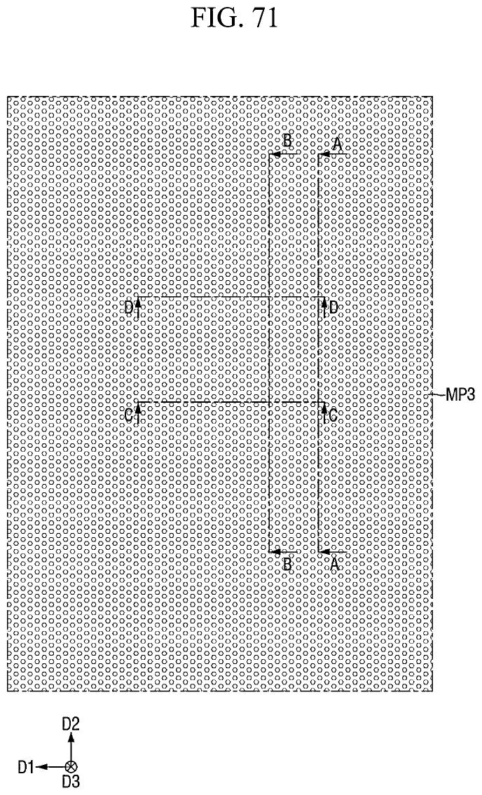

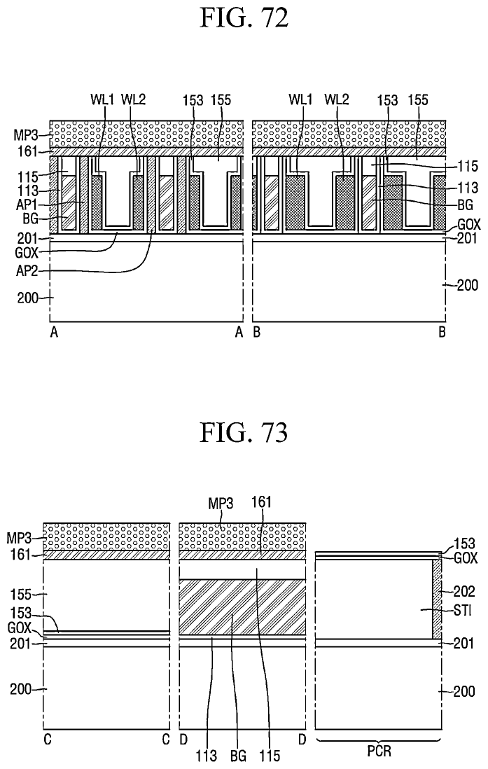

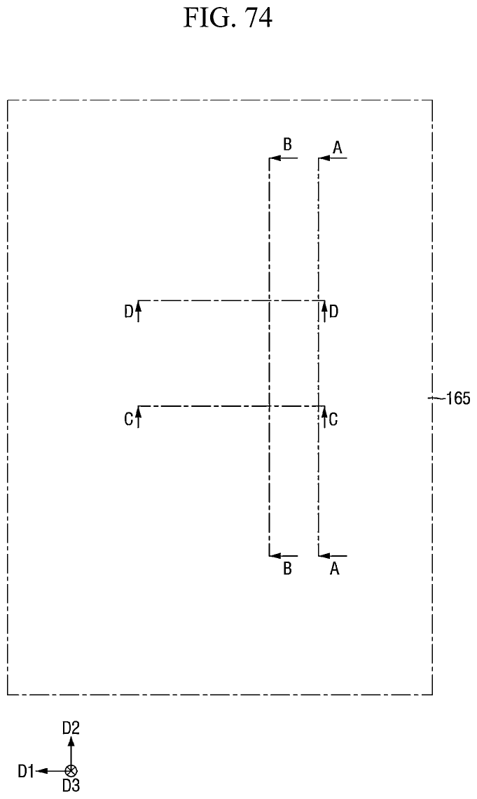

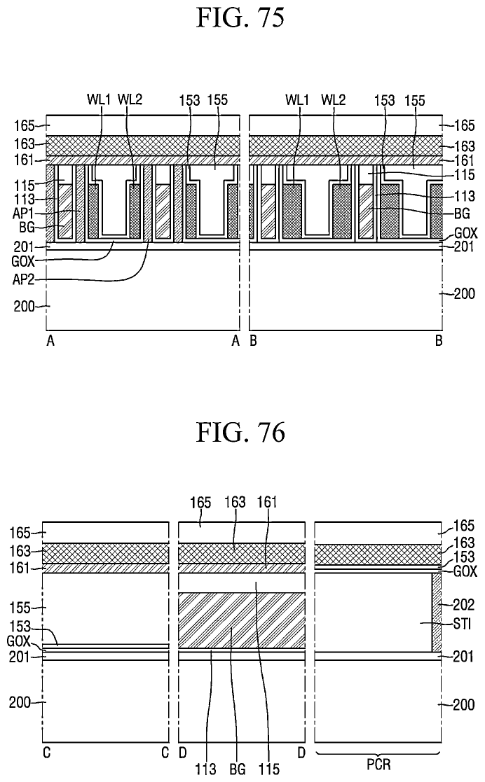

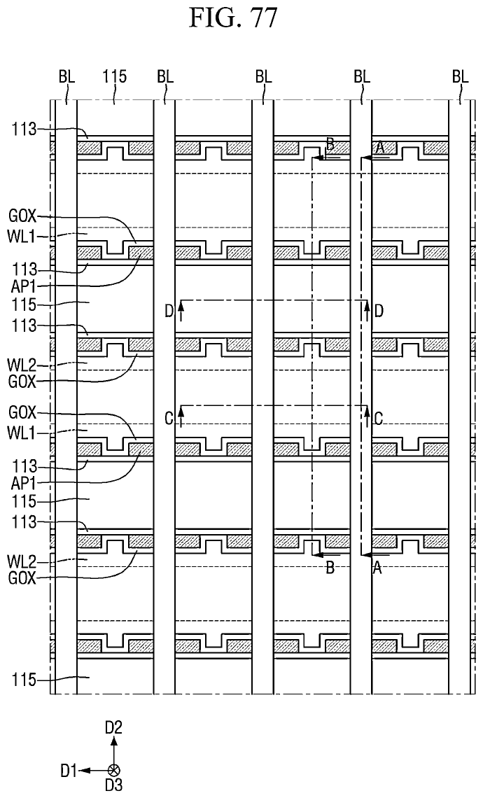

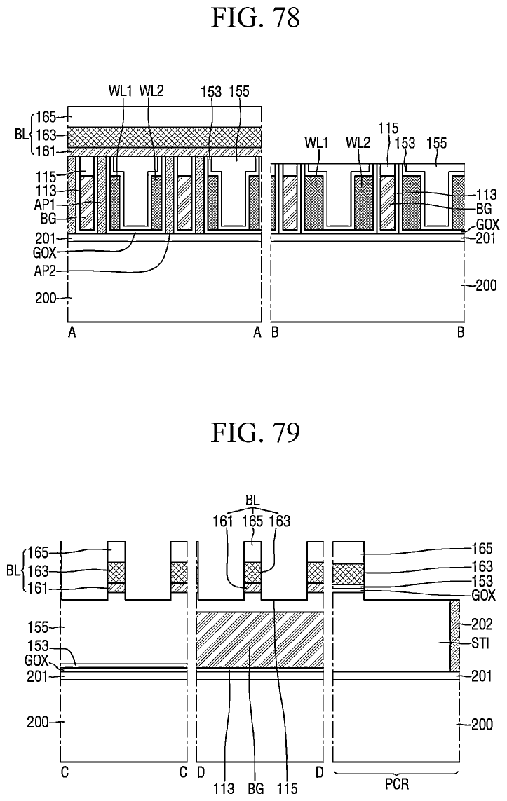

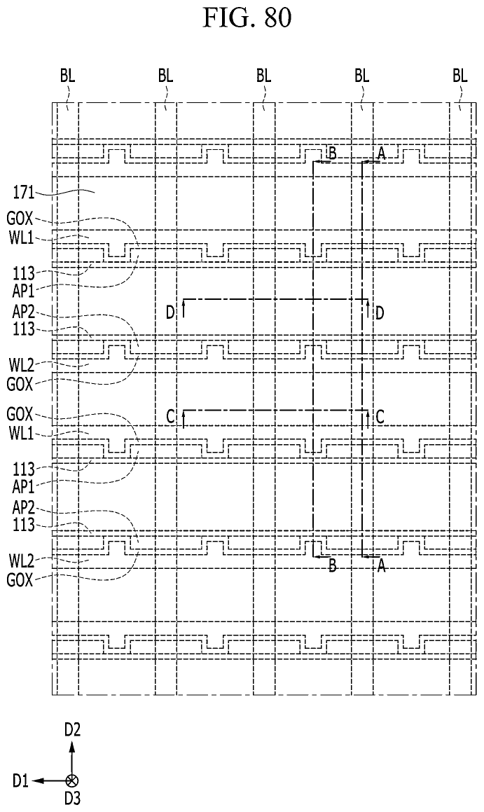

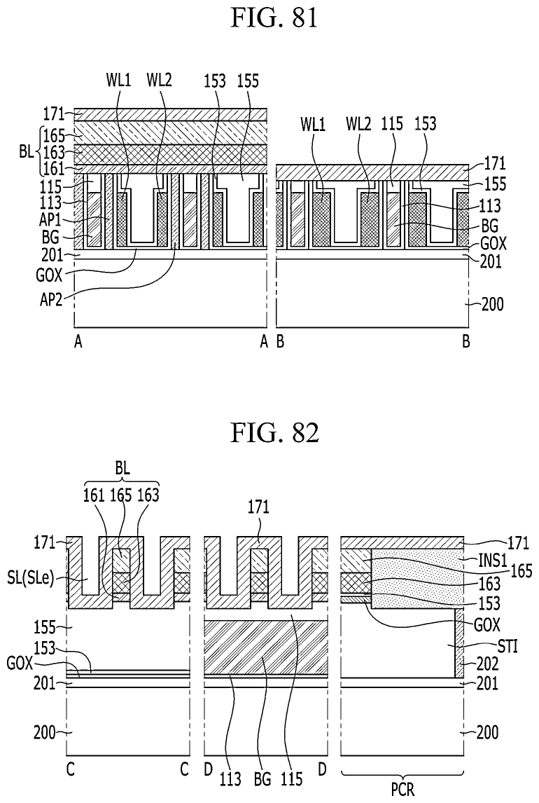

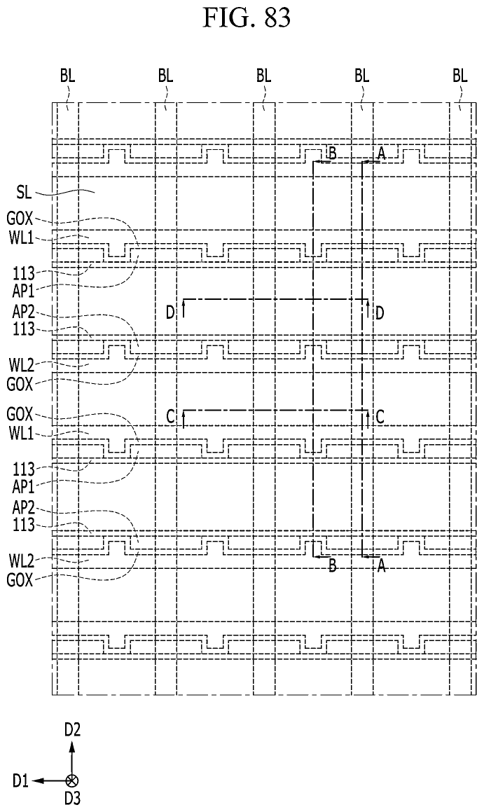

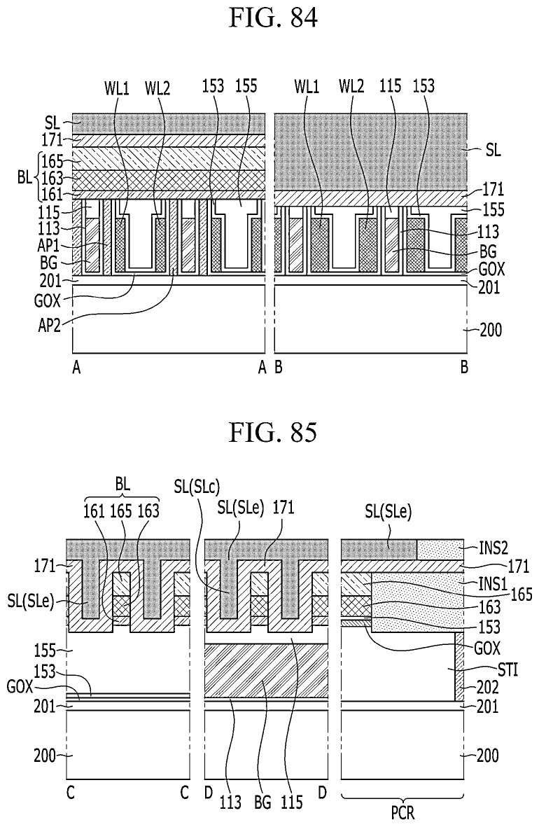

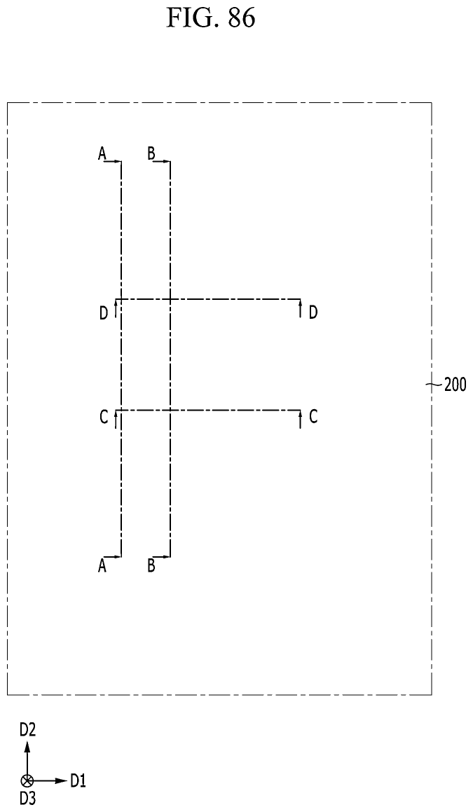

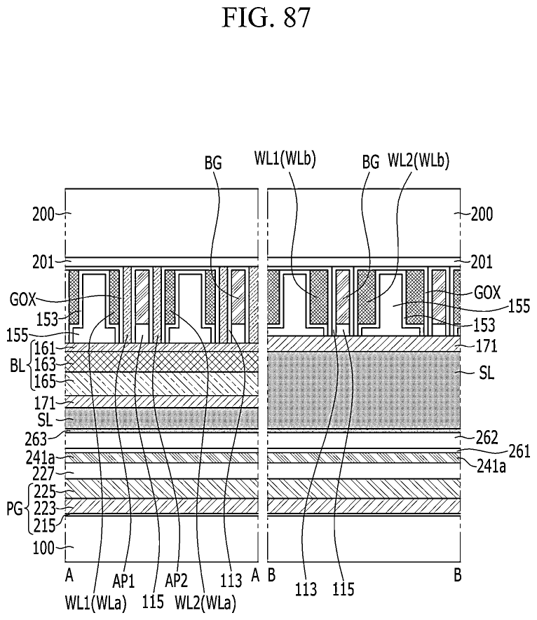

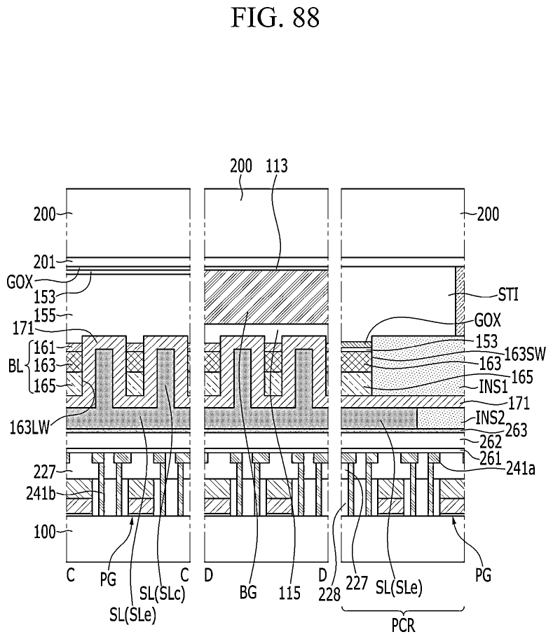

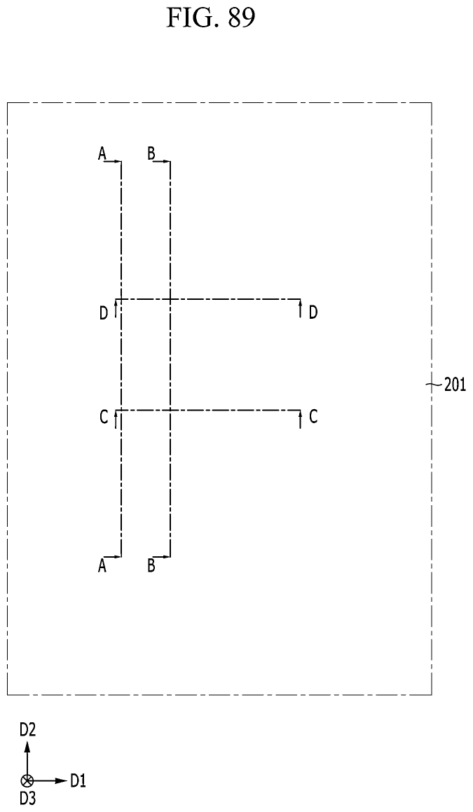

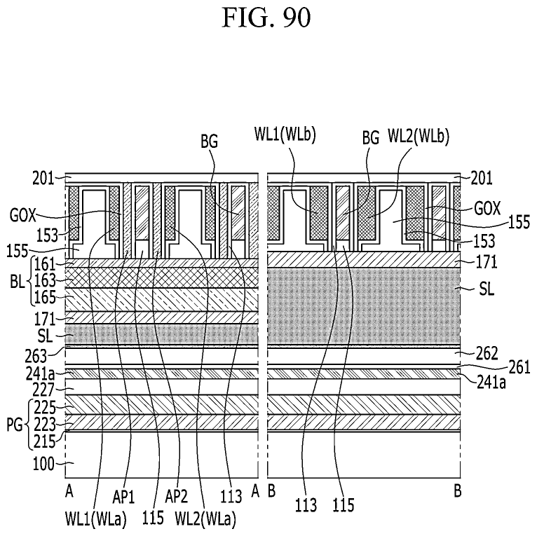

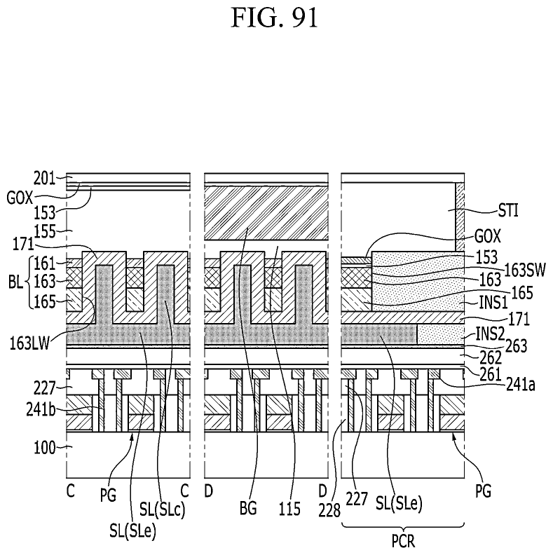

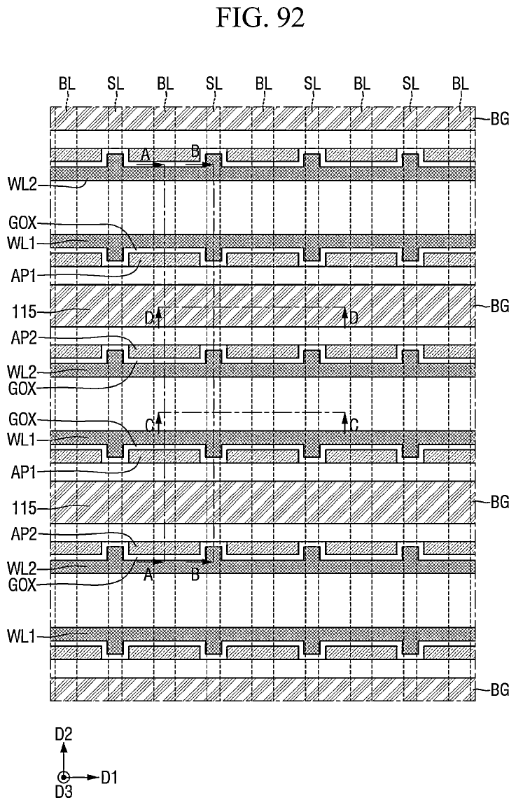

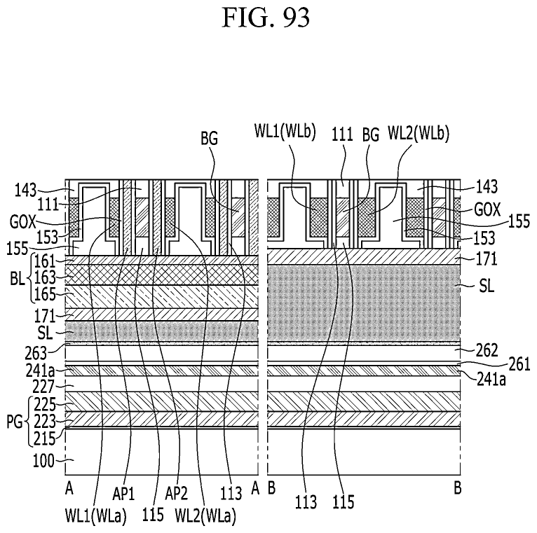

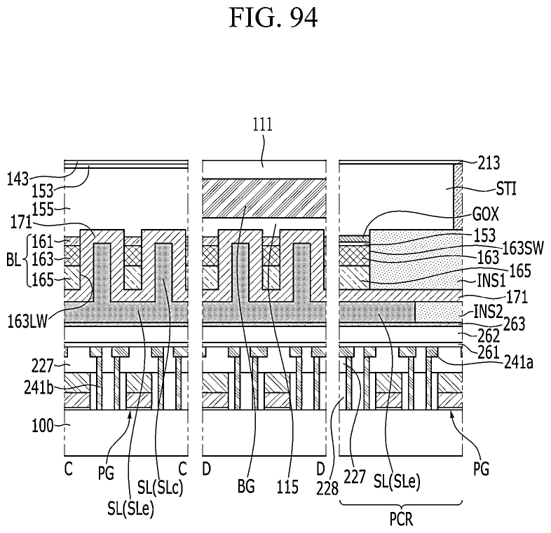

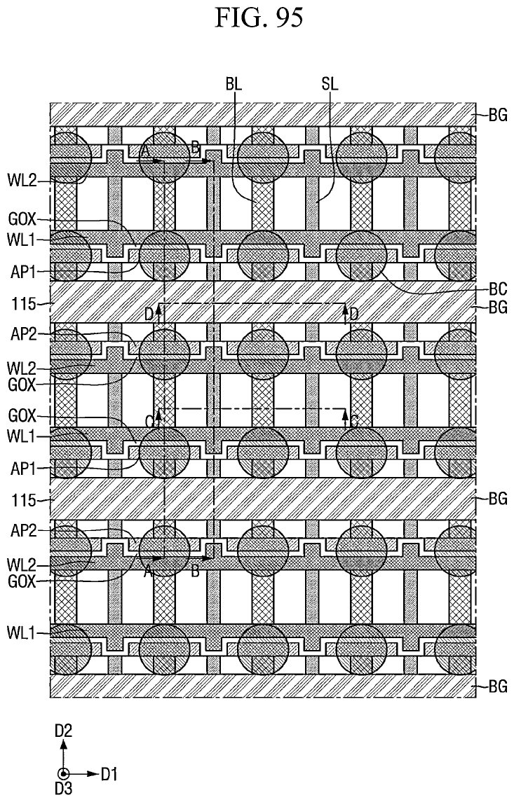

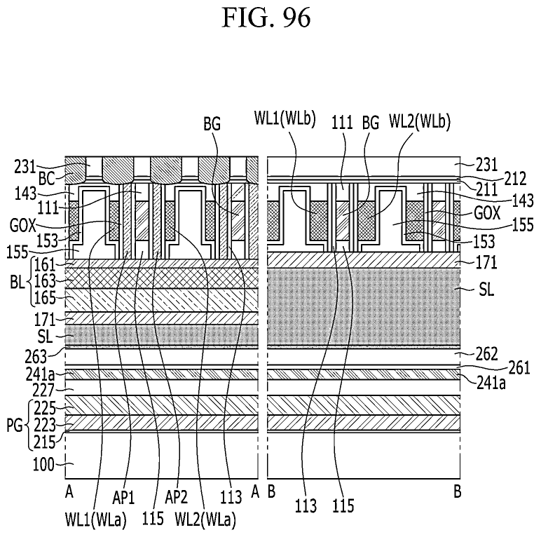

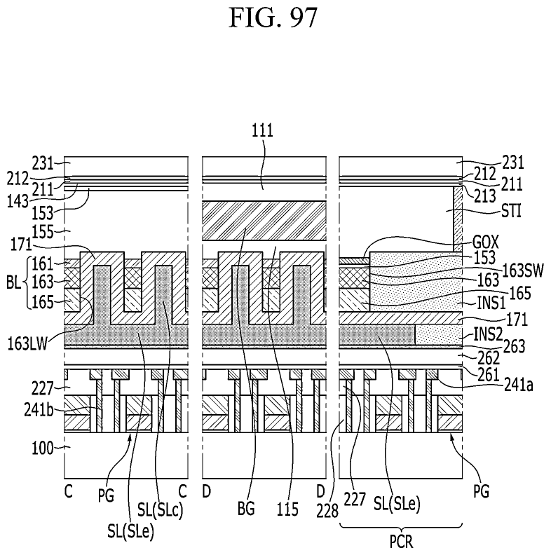

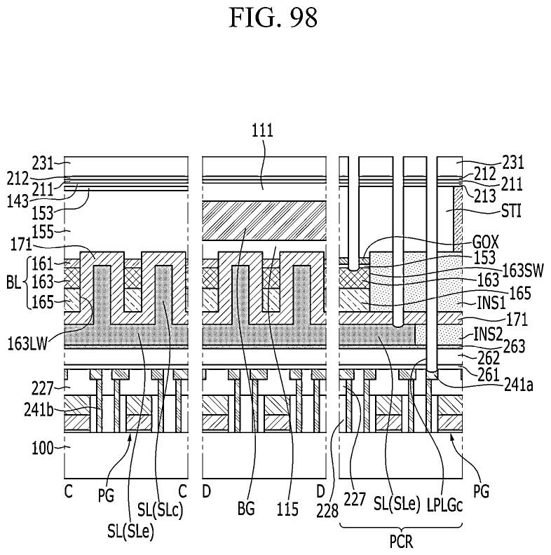

Referring to FIG. 98, a lower peripheral contact plug hole may be formed in the peripheral circuit region PCR.

The lower peripheral contact plug hole may expose the metal pattern 163 disposed at the end of the bit line BL, and the connection portion SLc of the shielding pattern SL, and the peripheral wire line 241a. The lower peripheral contact plug hole may be formed passing through the isolation layer STI.

Next, in FIG. 3 and FIG. 4, within the lower peripheral contact plug hole, lower peripheral contact plugs LPLGa, LPLGb, and LPLGc may be formed.

Subsequently, data storage patterns DSP may be formed on the contact pattern BC.

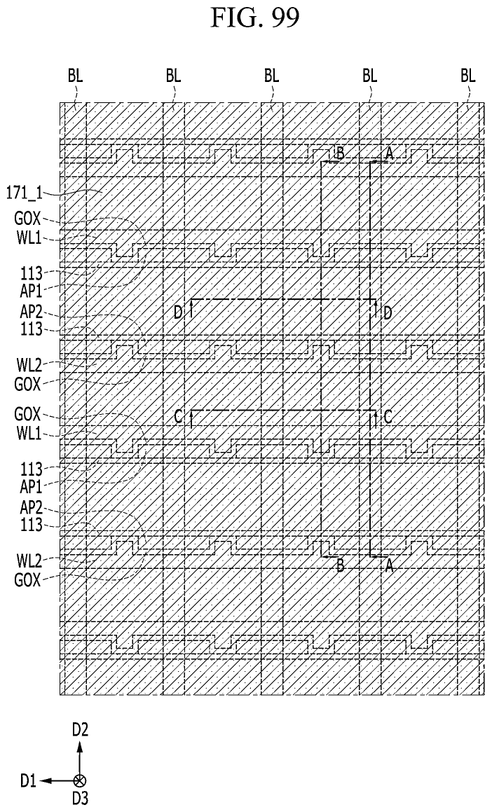

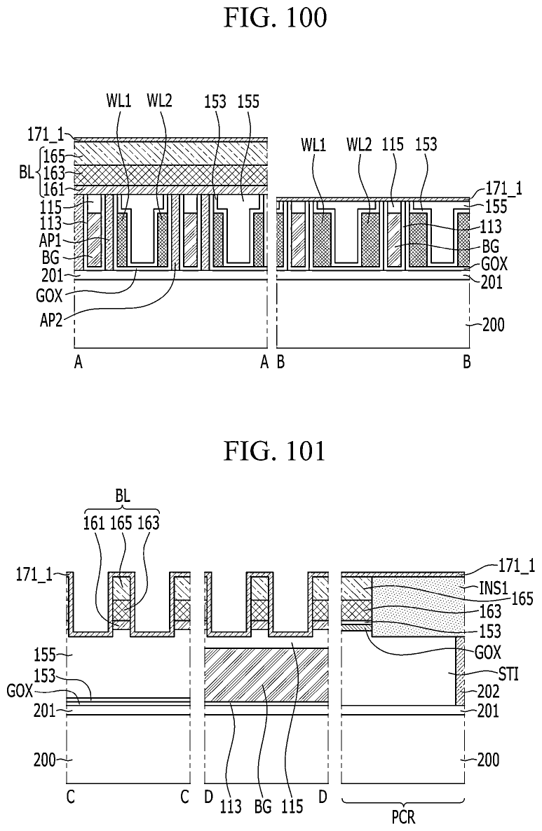

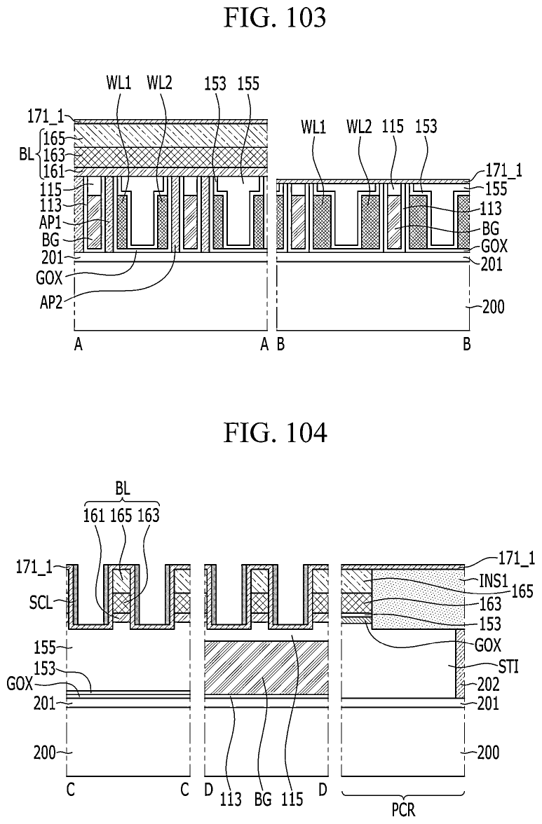

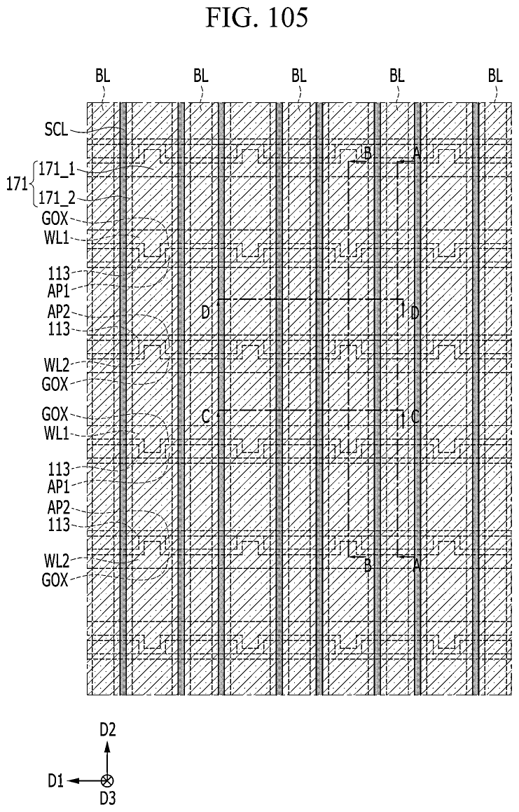

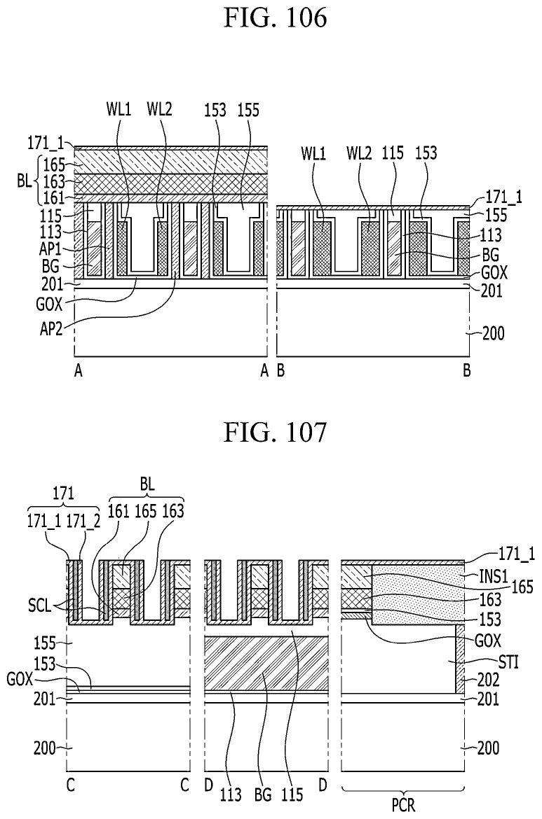

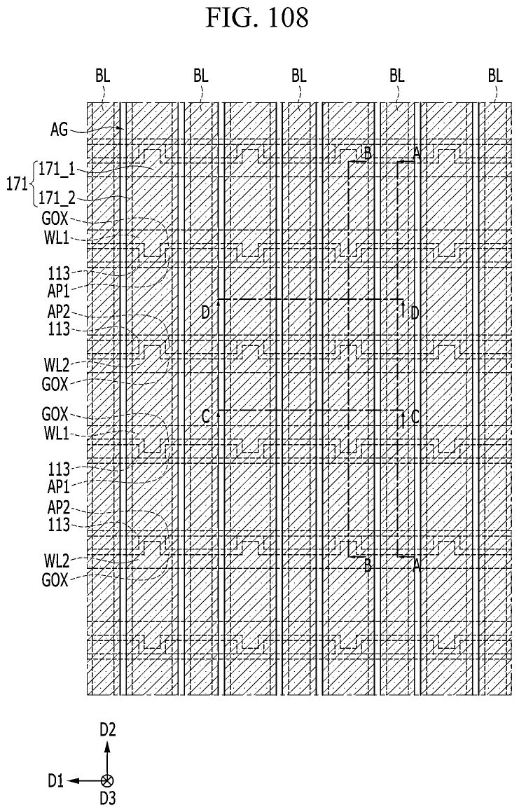

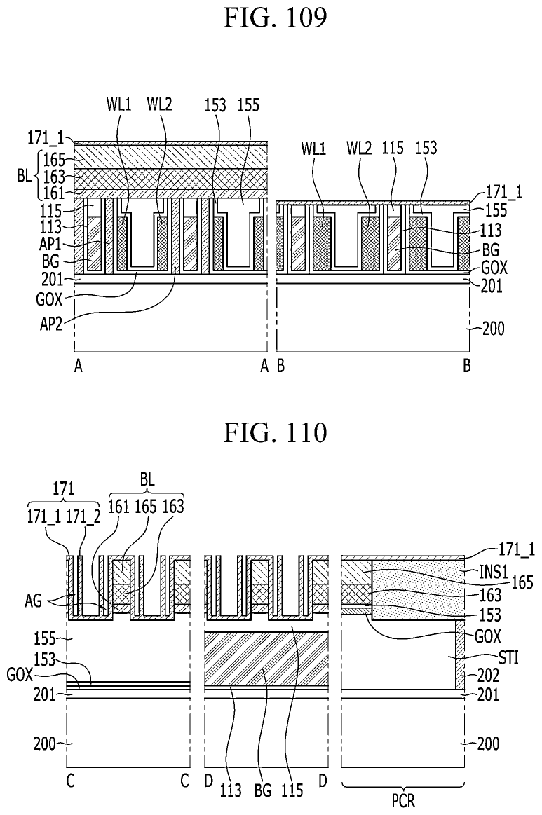

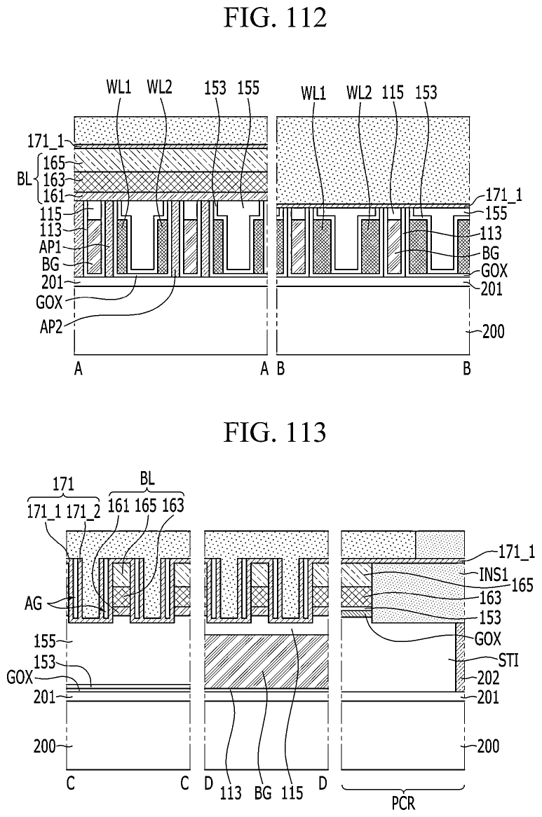

FIG. 99 to FIG. 113 are views to explain a method for manufacturing a semiconductor memory device according to various example embodiments and corresponding to steps of FIG. 80 to FIG. 85.

Referring to FIG. 99 to FIG. 101, the first portion 171_1 of the shielding insulation layer 171 may be formed along the sidewall of the bit line BL, the upper surface of the bit line BL, the sidewall of the second activation pattern AP2, and the upper surface of the back gate capping pattern 115.

The first portion 171_1 of the shielding insulation layer 171 may include an insulating material, for example, be formed by using at least one of a physical vapor deposit (PVD), a thermal chemical vapor deposition (a thermal CVD), a low-pressure chemical vapor deposition (LP-CVD), a plasma enhanced chemical vapor deposition (PE-CVD) or an atomic layer deposition (ALD), but it is not limited thereto.

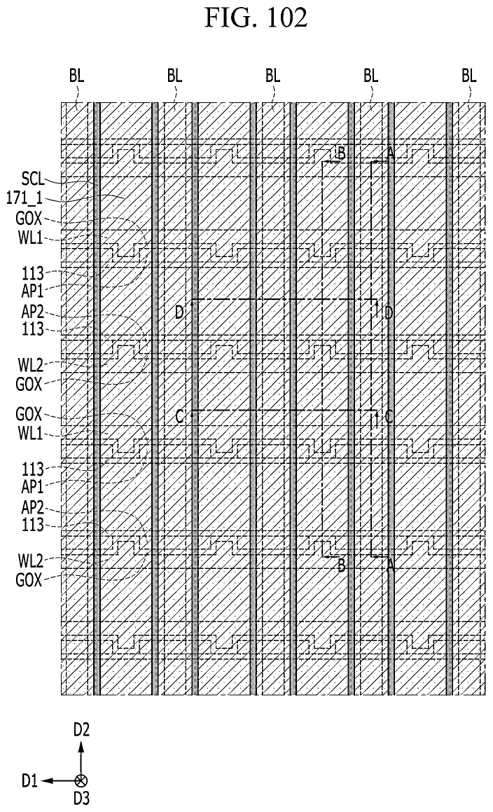

Referring to FIG. 102 to FIG. 104, a sacrificial layer SCL may be formed on the first portion 171_1 of the shielding insulation layer 171.

The sacrificial layer SCL may include a material having an etch rate different from the insulating material of the first portion 171_1 of the shielding insulation layer 171, and may include, for example, silicon nitride or carbon.

The sacrificial layer SCL may be formed using at least one of, for example, by a physical vapor deposition (PVD), a thermal chemical vapor deposition (a thermal CVD), a low pressure chemical vapor deposition (LP-CVD), a plasma enhanced chemical vapor deposition (PE-CVD), or an atomic layer deposition (ALD) techniques, but it is not limited thereto.

Subsequently, an anisotropic etching process for the sacrificial layer SCL may be performed. During the anisotropic etching process for the sacrificial layer SCL, the first portion 171_1 of the shielding insulation layer 171 may be used as an etch stopping layer. According to the anisotropic etching process for the sacrificial layer SCL, the sacrificial layer SCL may be cut and placed only on the side of the first portion 171_1 of the shielding insulation layer 171 in the first direction D1.

Referring to FIG. 105 to FIG. 107, the second portion 171_2 of the shielding insulation layer 171 may be formed along the first portion 171_1 of the shielding insulation layer 171 and the upper surface of the sacrificial layer SCL.

The second portion 171_2 of the shielding insulation layer 171 may include an insulating material, for example, may be formed using at least one of a physical vapor deposition (PVD), a thermal chemical vapor deposition (a thermal CVD), a low pressure chemical vapor deposition (LP-CVD), a plasma reinforced chemical vapor deposition (PE-CVD), or an atomic layer deposition (ALD) techniques, but it is not limited thereto.

Subsequently, an anisotropic etching process may be performed on the second portion 171_2 of the shielding insulation layer 171. During the anisotropic etching process for the second portion 171_2 of the shielding insulation layer 171, the sacrificial layer SCL may be used as an etch stopping layer. According to the anisotropic etching process for the second portion 171_2 of the shielding insulation layer 171, the second portion 171_2 of the shielding insulation layer 171 may be cut and placed only on the side of the sacrificial layer SCL in the first direction D1.

Referring to FIG. 108 to FIG. 110, the sacrificial layer SCL exposed between the first portion 171_1 and the second portion 171_2 of the shielding insulation layer 171 is removed.

As an example, the sacrificial layer SCL may be selectively removed by a dry etching using phosphoric acid or the like.

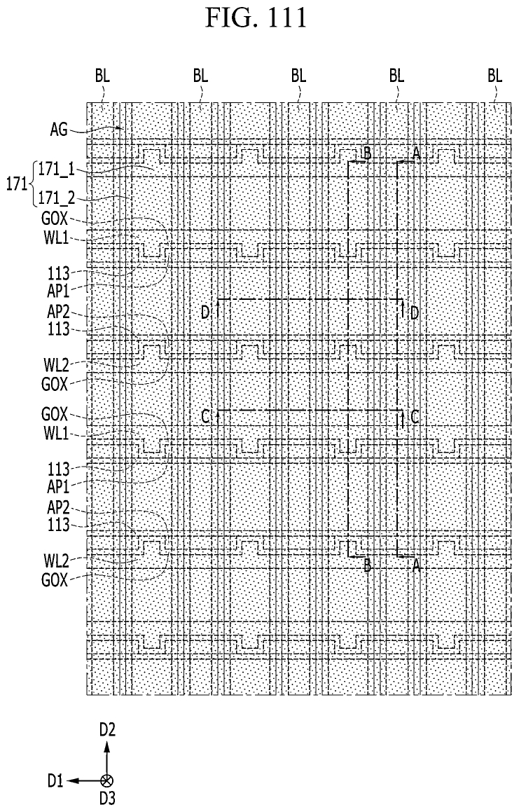

Referring to FIG. 111 to FIG. 113, the shielding structure SDS may be formed by forming the shielding pattern SL within the shielding region defined by the first portion 171_1 and the second portion 171_2 of the shielding insulation layer 171. At this time, the shielding pattern SL is not formed within the narrow region where the sacrificial layer SCL is removed, and an air gap AG may be formed.

For example, forming the shielding pattern SL may form a shielding conductive layer to fill the shielding region on the first portion 171_1 and the second portion 171_2 of the shielding insulation layer 171. Accordingly, the shielding pattern SL may include an extending portion SLc disposed within the shielding region of the shielding insulation layer 171 and extending in the second direction D2 and a body portion SLe covering the upper surface of the shielding insulation layer 171. Selectively, when recessing the upper surface of the shielding conductive layer, the shielding pattern SL may include only the extending portion SLc.

While example embodiments have been described in connection with what is presently considered to be practical embodiments, it is to be understood that the disclosure is not limited to the disclosed embodiments. On the contrary, it is intended to cover various modifications and equivalent arrangements included within the spirit and scope of the appended claims. Additionally example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a peripheral gate structure on a substrate;
a bit line on the peripheral gate structure, and extending in a second direction different from a first direction;
a shielding structure on the peripheral gate structure, adjacent to the bit line, and extending in the second direction;
a back gate electrode on the bit line and the shielding structure and extending in the first direction;
a first word line on the bit line and the shielding structure, extending in the first direction and on one side of the back gate electrode in the second direction, and a second word line on the bit line and the shielding structure and on another side of the back gate electrode; and
a first activation pattern on the bit line and between the back gate electrode and the first word line and a second activation pattern between the back gate electrode and the second word line,
wherein the shielding structure includes a low-dielectric material.

2. The semiconductor memory device of claim 1, wherein:
a dielectric constant of the low-dielectric material is less than that of silicon oxide (SiO₂).

3. The semiconductor memory device of claim 2, wherein:
the low-dielectric material includes a hydrocarbon compound, carbide, carbon, or a combination thereof.

4. The semiconductor memory device of claim 2, wherein:
the low-dielectric material includes at least one of carbon doping silicon oxide (SiOC) or porous silicon oxide.

5. The semiconductor memory device of claim 1, wherein:
the shielding structure includes a shielding pattern, and a shielding insulation layer between the shielding pattern and the bit line.

6. The semiconductor memory device of claim 5, wherein:
the shielding pattern includes a conductive material, and
the shielding insulation layer includes the low-dielectric material.

7. The semiconductor memory device of claim 5, wherein:
the shielding pattern includes the low-dielectric material, and
the shielding insulation layer includes an insulating material.

8. The semiconductor memory device of claim 1, wherein:
the shielding structure includes a body portion below the bit line and extending in the first direction and the second direction, and an extension portion between the bit lines and extending in the second direction.

9. The semiconductor memory device of claim 1, wherein:
the first activation pattern and the second activation pattern include a monocrystalline semiconductor material.

10. The semiconductor memory device of claim 1, further comprising:
a bonding insulation layer between the peripheral gate structure and the bit line.

11. A semiconductor memory device comprising:
a peripheral gate structure on a substrate;
a bit line on the peripheral gate structure, and extending in a second direction different from a first direction;
a shielding structure adjacent to the bit line on the peripheral gate structure and extending in the second direction;
a back gate electrode on the bit line and the shielding structure and extending in the first direction;
a first word line on the bit line and the shielding structure, extending in the first direction and on one side of the back gate electrode in the second direction, and a second word line on the bit line and the shielding structure and on another side of the back gate electrode; and
a first activation pattern on the bit line between the back gate electrode and the first word line and a second activation pattern placed the back gate electrode and the second word line,
wherein the shielding structure has an air gap.

12. The semiconductor memory device of claim 11, wherein:
the shielding structure includes a shielding pattern and a shielding insulation layer between the shielding pattern and the bit line.

13. The semiconductor memory device of claim 12, wherein:
the shielding pattern includes a low-dielectric material, and
the shielding insulation layer has the air gap.

14. The semiconductor memory device of claim 12, wherein:
the shielding pattern includes a conductive material, and
the shielding insulation layer has the air gap.

15. The semiconductor memory device of claim 12, wherein:
the shielding pattern includes an insulating material, and
the shielding insulation layer has the air gap.

16. The semiconductor memory device of claim 15, wherein:
the shielding pattern has a second air gap.

17. The semiconductor memory device of claim 15, wherein:
the shielding structure has the air gap between the shielding pattern and the shielding insulation layer.

18. The semiconductor memory device of claim 12, wherein:
one end of the air gap in a third direction different from the first direction and the second direction is in contact with the shielding pattern, and
another end of the air gap in the third direction is surrounded by the shielding insulation layer.

19. The semiconductor memory device of claim 11, wherein:
the bit line includes a bit line mask pattern, a metal pattern, and a polysilicon pattern sequentially stacked in a third direction different from the first direction and the second direction, and
the air gap extends in the third direction and overlaps the metal pattern in the first direction.

20. A semiconductor memory device comprising:
a peripheral gate structure on a substrate;
a bit line on the peripheral gate structure, and extending in a second direction different from a first direction;
a shielding structure adjacent to the bit line on the peripheral gate structure and extending in the second direction;
a back gate electrode on the bit line and the shielding structure and extending in the first direction;
a first word line extending in the first direction and on one side of the back gate electrode in the second direction, and a second word line placed on another side of the back gate electrode, the first and second word lines on the bit line and the shielding structure; and
a first activation pattern between the back gate electrode and the first word line and a second activation pattern between the back gate electrode and the second word line, the first and second activation patterns on the bit line,
wherein the shielding structure includes a shielding pattern, and a shielding insulation layer placed between the shielding pattern and the bit line,
the shielding pattern includes a conductive material, and
the shielding insulation layer includes a low-dielectric material, and/or the shielding insulation layer has an air gap.
